(19) United States
(12) Patent Application Publication
(10) Pub. No.: US 2026/0313896 A1
(43) Pub. Date: Oct. 8, 2026

(54) SEMICONDUCTOR DEVICE WITH ALIGNED CHANNEL STRUCTURES AND GATE CONTACT STRUCTURES

(71) Applicant: Samsung Electronics Co., Ltd., Suwon-si (KR)

(72) Inventors: Sanghyun Han, Suwon-si (KR); Eunseok Choi, Suwon-si (KR)

(21) Appl. No.: 19/562,434

(22) Filed: Mar. 10, 2026

(30) Foreign Application Priority Data
Apr. 7, 2025 (KR) 10-2025-0044913

(51) Int. Cl. H10B 43/27; G11C 5/06; H10B 41/10; H10B 41/27; H10B 41/35; H10B 43/10; H10B 43/35; H10D 80/30; H10W 90/00

(52) U.S. Cl. CPC H10B 43/27; G11C 5/063; H10B 41/10; H10B 41/27; H10B 41/35; H10B 43/10; H10B 43/35; H10D 80/30; H10W 90/792

(57) ABSTRACT

A semiconductor device includes gate electrodes stacked and spaced apart from each other in a first direction; interlayer insulating layers alternately stacked with the gate electrodes; channel structures extending into the gate electrodes in the first direction and each including a channel layer; gate contact plugs extending into the gate electrodes in the first direction and electrically connected to the gate electrodes; common source layers in contact with the channel layers on the channel structures; cell region insulating layers below the channel structures and the gate contact plugs; and bitlines electrically connected to the channel structures in the cell region insulating layer. Lower ends of the channel structures and lower ends of the gate contact plugs are in an insulating structure including a lowermost interlayer insulating layer and the cell region insulating layer.

### CROSS-REFERENCE TO RELATED APPLICATIONS

This application claims benefit of priority to Korean Patent Application No. 10-2025-0044913 filed on Apr. 7, 2025 in the Korean Intellectual Property Office, the disclosure of which is incorporated herein by reference in its entirety.

### BACKGROUND

A semiconductor device may be used to store high-capacity data in a data storage system. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

Some example embodiments of the present disclosure is to provide a semiconductor device having improved reliability and electrical properties.

Some example embodiments of the present disclosure is to provide a data storage system including a semiconductor device having improved reliability and electrical properties.

In example embodiments of the present disclosure, a semiconductor device includes a first semiconductor structure including a substrate, circuit elements on the substrate, a first interconnection structure on the circuit elements, and first bonding pads on the first interconnection structure; and a second semiconductor structure on the first semiconductor structure, wherein the second semiconductor structure includes gate electrodes stacked and spaced apart from each other in a first direction perpendicular to an upper surface of the substrate; interlayer insulating layers alternately stacked with the gate electrodes; channel structures extending into the gate electrodes in the first direction and each including a channel layer; gate contact plugs extending into the gate electrodes in the first direction and electrically connected to the gate electrodes, respectively; common source layers covering upper ends of the channel structures and in contact with the channel layers; second interconnection structures including bitlines electrically connected to the channel structures, respectively, below lower ends of the channel structures; and second bonding pads below the second interconnection structure and connected to the first bonding pads, wherein each of the channel structures includes a plurality of channel portions stacked in the first direction, wherein each of the gate contact plugs includes a plurality of contact portions stacked in the first direction, wherein, in at least one of the plurality of channel portions, a width of an upper surface is the same as or greater than a width of a lower surface, and wherein, in at least one of the plurality of contact portions, a width of an upper surface is the same as or greater than a width of a lower surface.

In example embodiments of the present disclosure, a semiconductor device includes gate electrodes stacked and spaced apart from each other in a first direction perpendicular to an upper surface of a substrate; interlayer insulating layers alternately stacked with the gate electrodes; channel structures extending into the gate electrodes in the first direction and each including a channel layer; gate contact plugs extending into the gate electrodes in the first direction and electrically connected to the gate electrodes, respectively; common source layers in contact with the channel layers on the channel structures; cell region insulating layers below the channel structures and the gate contact plugs; and bitlines electrically connected to the channel structures, respectively, in the cell region insulating layer, wherein each of the channel structures includes first to third channel portions stacked in order from a lower portion, wherein at least the third channel portion includes a region having an inclined side surface such that a width thereof decreases toward the substrate, and wherein lower ends of the channel structures and lower ends of the gate contact plugs are in an insulating structure including a lowermost interlayer insulating layer among the interlayer insulating layers and the cell region insulating layer.

In example embodiments of the present disclosure, a data storage system includes a semiconductor storage device including a first semiconductor structure including circuit elements, a second semiconductor structure on the first semiconductor structure, and an input/output pad electrically connected to the circuit elements; and a controller electrically connected to the semiconductor storage device through the input/output pads, wherein the second semiconductor structure includes gate electrodes stacked and spaced apart from each other in a first direction perpendicular to an upper surface of the first semiconductor structure; interlayer insulating layers alternately stacked with the gate electrodes; channel structures extending into the gate electrodes in the first direction and each including a channel layer; gate contact plugs extending into the gate electrodes in the first direction and electrically connected to the gate electrodes, respectively; a common source layer in contact with the channel layer on the channel structures; a cell region insulating layer below the channel structures and the gate contact plugs; and bitlines electrically connected to the channel structures, respectively, in the cell region insulating layer, wherein each of the channel structures includes first to third channel portions stacked in order from a lower portion, wherein each of the gate contact plugs includes first to third contact portions stacked in order from a lower portion, and wherein each of the third channel portion and the third contact portion includes a region having an inclined side surface such that a width thereof decreases toward the substrate.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to example embodiments of the present disclosure;

FIGS. 2A and 2B are cross-sectional views illustrating a semiconductor device according to example embodiments of the present disclosure;

FIG. 3 is an enlarged views illustrating partial regions of a semiconductor device according to example embodiments of the present disclosure;

FIGS. 4A, 4B, and 4C are a cross-sectional diagram, an enlarged diagram, and a view illustrating a semiconductor device according to example embodiments of the present disclosure;

FIGS. 5A and 5B are cross-sectional views illustrating a semiconductor device according to example embodiments of the present disclosure;

FIGS. 6A and 6B are cross-sectional views illustrating a semiconductor device according to example embodiments of the present disclosure;

FIG. 7 is a cross-sectional view illustrating a semiconductor device according to example embodiments of the present disclosure;

FIGS. 8A and 8B are cross-sectional views illustrating a semiconductor device according to example embodiments of the present disclosure;

FIGS. 9A and 9B are cross-sectional and enlarged views illustrating a semiconductor device according to example embodiments of the present disclosure;

FIGS. 10A, 10B, 10C, 10D, 10E, 10F, 10G and 10H are cross-sectional views illustrating a semiconductor device according to example embodiments of the present disclosure;

FIGS. 11A, 11B. and 11C are cross-sectional views illustrating a method of manufacturing a semiconductor device according to example embodiments of the present disclosure;

FIG. 12 is a view illustrating a data storage system including a semiconductor device according to example embodiments of the present disclosure; and

FIG. 13 is a perspective view illustrating a data storage system including a semiconductor device according to example embodiments of the present disclosure.

### DETAILED DESCRIPTION

Hereinafter, embodiments of the present disclosure will be described as follows with reference to the accompanying drawings.

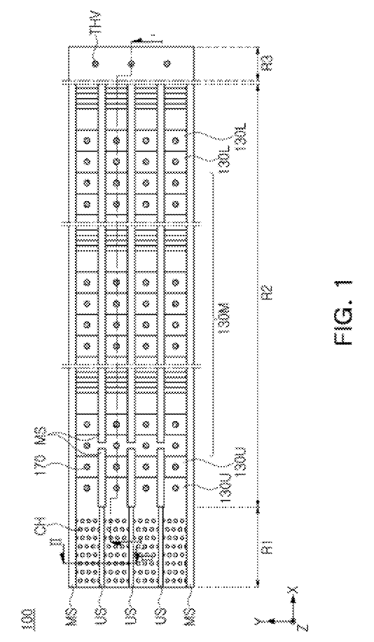

FIG. 1 is a plan view illustrating a semiconductor device according to example embodiments.

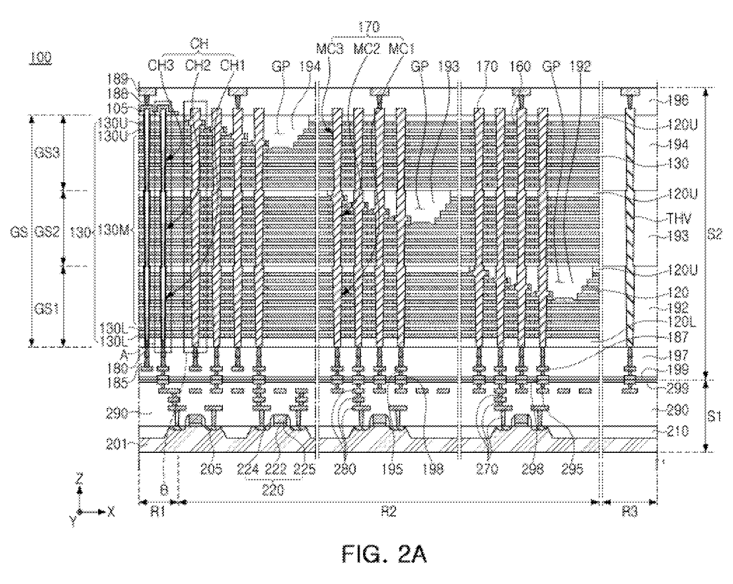

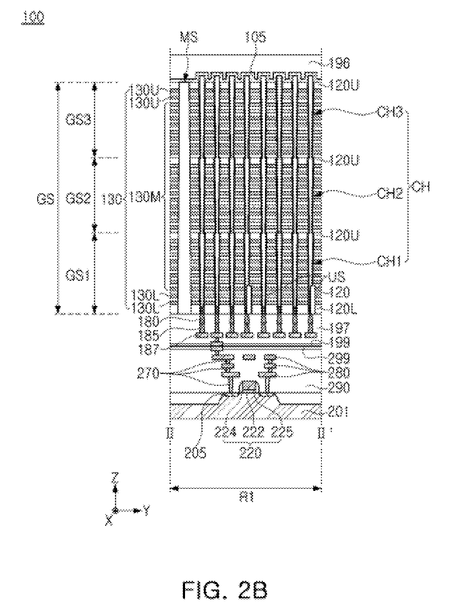

FIGS. 2A and 2B are cross-sectional views illustrating a semiconductor device according to example embodiments, taken along lines I-I’ and II-II’ in FIG. 1.

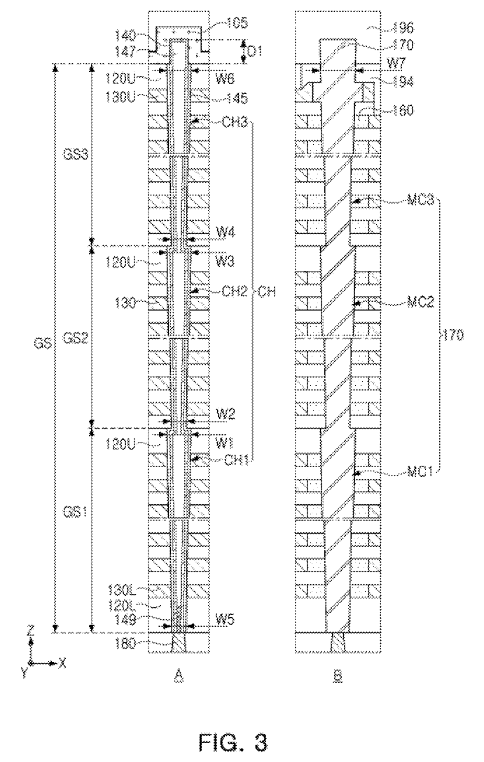

FIG. 3 is an enlarged views illustrating partial regions of a semiconductor device according to example embodiments, illustrating regions “A” and “B” in FIG. 2A.

Referring to FIGS. 1, 2A, 2B, and 3, a semiconductor device 100 may include first and second semiconductor structures S1 and S2 bonded to each other vertically. The first semiconductor structure S1 may include a peripheral circuit region, and the second semiconductor structure S2 may include a memory cell region. In some example embodiments, the second semiconductor structure S2 may be disposed below the first semiconductor structure S1. FIG. 1 illustrates the arrangement of a portion of elements of the second semiconductor structure S2 on a plane.

A first semiconductor structure S1 may include a substrate 201, source/drain regions 205 and device isolation layers 210 in the substrate 201, circuit elements 220 disposed on the substrate 201, a peripheral region insulating layer 290, circuit contact plugs 270, circuit interconnection lines 280, first bonding vias 295, first bonding pads 298, and a first bonding insulating layer 299.

The substrate 201 may have an upper surface extending in the X-direction and the Y-direction. An active region may be defined in the substrate 201 by the device isolation layers 210. The source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include a planar transistor. Each of the circuit elements 220 may include a circuit channel dielectric layer 222, a spacer layer 224, and a circuit gate electrode 225. The source/drain regions 205 may be disposed as source/drain regions in the substrate 201 on both sides of the circuit gate electrode 225.

A peripheral region insulating layer 290 may be disposed to cover the circuit elements 220 on an upper surface of the substrate 201. The peripheral region insulating layer 290 may include a plurality of insulating layers formed by different processes. The peripheral region insulating layer 290 may be formed of an insulating material.

The circuit contact plugs 270 and the circuit interconnection lines 280 may form a first interconnection structure electrically connected to the circuit elements 220 and the source/drain regions 205. The circuit contact plugs 270 may have a cylindrical shape, and the circuit interconnection lines 280 may have a line shape. An electrical signal may be applied to the circuit elements 220 by the circuit contact plugs 270 and the circuit interconnection lines 280. The circuit contact plugs 270 may also be connected to the circuit gate electrode 225. The circuit interconnection lines 280 may be connected to the circuit contact plugs 270 and may be disposed in a plurality of layers. The circuit contact plugs 270 and the circuit interconnection lines 280 may include a conductive material, for example, tungsten (W), copper (Cu), aluminum (Al), or the like, and each of the components may further include a diffusion barrier. In example embodiments, the number of layers of the circuit contact plugs 270 and the circuit interconnection lines 280 may be varied.

The first bonding vias 295, the first bonding pads 298, and the first bonding insulating layer 299 may be included in the first bonding structure and may be disposed on the uppermost circuit interconnection lines 280. The first bonding vias 295 may have a cylindrical shape, and the first bonding pads 298 may have a circular pad shape or a relatively short line shape on a plane. Upper surfaces of the first bonding pads 298 may form a portion of an upper surface of the first semiconductor structure S1. The first bonding vias 295 and the first bonding pads 298 may provide an electrical connection path to the second semiconductor structure S2. In example embodiments, a portion of the first bonding pads 298 may be disposed only for bonding without being connected to the circuit interconnection lines 280. The first bonding vias 295 and the first bonding pads 298 may include a conductive material, for example, copper (Cu).

The first bonding insulating layer 299 may be disposed on an upper surface of the peripheral region insulating layer 290 by a predetermined thickness. The first bonding insulating layer 299 may be provided for dielectric-dielectric bonding with the second bonding insulating layer 199 of the second semiconductor structure S2. The first bonding insulating layer 299 may also function as a diffusion barrier for the first bonding pads 298 and may include, for example, at least one of SiO, SiN, SiCN, SiOC, SiON, or SiOCN.

The second semiconductor structure S2 may have first to third regions R1 and R2, and R3. The second semiconductor structure S2 may include gate electrodes 130 vertically stacked and forming a gate structure GS, interlayer insulating layers 120 alternately stacked with the gate electrodes 130 and forming the gate structure GS, channel structures CH disposed to penetrate the gate structure GS in the first region R1, a common source layer 105 covering upper ends of the channel structures CH, first isolation regions MS extending by penetrating the gate structure GS, second isolation regions US penetrating a portion disposed in a lower portion of the gate electrodes 130, and gate contact plugs 170 connected to the gate electrodes 130 in the second region R2 and extending vertically.

The second semiconductor structure S2 may be configured as a second interconnection structure, and may further include studs 180, first cell contact plugs 185, and first cell interconnection lines 187 below the channel structures CH and the gate contact plugs 170. The second semiconductor structure S2 may be configured as a second bonding structure, and may further include second bonding vias 195, second bonding pads 198, and second bonding insulating layer 199. The second semiconductor structure S2 may further include first to fifth cell region insulating layers 192, 193, 194, 196, and 197 covering the gate electrodes 130, second cell contact plugs 188, second cell interconnection lines 189, and through-contact plug THV.

In the second semiconductor structure S2, in the first region R1, the gate electrodes 130 may be vertically stacked and the channel structures CH may be disposed, and memory cells may be disposed the first region R1. In the second region R2, the gate electrodes 130 may extend to different lengths and may form gate pad regions GP and may correspond to a region for electrically connecting the memory cells to the first semiconductor structure S1. The second region R2 may be disposed on at least one end of the first region R1 in at least one direction, for example, the X-direction. In the third region R3, there may be no gate electrodes 130, and a through-contact plug THV may be disposed. The third region R3 may be disposed on at leasdt one end of the second region R2 in at least one direction, for example, the X-direction.

The gate electrodes 130 may be stacked and spaced apart from each other in a direction perpendicular to an upper surface of the substrate 201, for example, in the Z-direction, and may form a gate structure GS together with interlayer insulating layers 120. The gate structure GS may include first to third stack structures GS1, GS2, and GS3 stacked vertically. However, in example embodiments, the gate stack structure may be formed as a single stack structure or may include four or more stack structures. The number of gate electrodes 130 included in each of the first to third stack structures GS1, GS2, and GS3 may be the same or different.

Gate electrodes 130 may include lower gate electrodes 130L forming gates of string select transistors, memory gate electrodes 130M forming a plurality of memory cells, and upper gate electrodes 130U forming gates of ground select transistors. The number of the memory gate electrodes 130M included in memory cells may be determined depending on the capacity of the semiconductor device 100. In some example embodiments, the number of the upper and lower gate electrodes 130U and 130L may be 1 to 4 or more, respectively, and may have a structure the same as or different from the structure of the memory gate electrodes 130M. In some example embodiments, the gate electrodes 130 may further include gate electrodes 130 disposed adjacent to the upper gate electrodes 130U and/or the lower gate electrodes 130L and forming an erase transistor used for an erase operation using the gate induced drain leakage (GIDL) phenomenon. Also, a portion of the gate electrodes 130, for example, memory gate electrodes 130M adjacent to the upper or lower gate electrodes 130U and 130L, may be dummy gate electrodes.

As illustrated in FIG. 1, the gate electrodes 130 may be isolated from each other in the Y-direction by the first isolation regions MS extending consecutively from the first region R1 and the second region R2. The gate electrodes 130 between a pair of first isolation regions MS may form one memory block, but the range of the memory block is not limited thereto. A portion of the gate electrodes 130, for example, the memory gate electrodes 130M, may form one layer in one memory block.

The gate electrodes 130 may be stacked vertically and spaced apart from each other on the first region R1, may extend from the first region R1 to the second region R2 by different lengths and may form step structures of a staircase shape in the gate pad regions GP. As illustrated in FIG. 2A, the gate electrodes 130 may have a form in which the gate pad regions GP are removed from an upper portion of one of the first to third stack structures GS1, GS2, and GS3 to a predetermined depth. The gate pad regions GP may be disposed to not overlap each other in the Z-direction. On the gate pad regions GP of the first and second stack structures GS1 and GS2 in a lower portion, the gate electrodes 130 included in the second and third stack structures GS2 and GS3 in an upper portion, respectively, may extend horizontally.

The gate pad regions GP may be disposed in order from the first region R1 in the X-direction to the third stack structure GS3, the second stack structure GS2, and the first stack structure GS1, but example embodiments thereof are not limited thereto. One gate pad region GP may be disposed in each of the first to third stack structures GS1, GS2, and GS3, or a plurality of the gate pad regions GP may be disposed in each of the first to third stack structures GS1, GS2, and GS3. However, the arrangement shape, arrangement order, and depth of the gate pad regions GP in example embodiments may be varied. In some example embodiments, the gate electrodes 130 may not be disposed on the gate pad regions GP.

The gate electrodes 130 may form first and second step structures in an asymmetrical shape in the X-direction in each of the gate pad regions GP. The first step structure may be configured as a staircase structure relatively adjacent to the first region R1 and having a level decreasing in the X-direction, and the second step structure may be configured as a staircase structure relatively far from the first region R1 and having a level increasing in the X-direction. For example, in each of the gate pad regions GP, a slope of the first step structure may be smaller than a slope of the second step structure in the first region R1. However, in some example embodiments, the first and second step structures may have a symmetrical shape. In the first step structure, the gate electrodes 130 may be connected to the gate contact plugs 170, and in the second step structure, the gate electrodes 130 may form a dummy region or a dummy structure not connected to the gate contact plugs 170. However, in some example embodiments, the specific shape of the step structure, and the number of gate electrodes 130 included in each step structure are not limited to the examples illustrated in FIG. 2A. In some example embodiments, the gate electrodes 130 may be disposed to have step structures in the Y-direction as well.

By the first step structure, the gate electrodes 130 may have end regions in which the gate electrode 130 in a lower portion extends longer than the gate electrode 130 in an upper portion and are exposed upwardly from the interlayer insulating layers 120. The gate electrodes 130 may be connected to the gate contact plugs 170 in the end regions, respectively. The gate electrodes 130 may have a form in which a thickness increases in the end regions. The gate electrodes 130 may include the first region R1 such that the gate electrodes 130 may have a thickness greater in the end regions than in the regions in which the other gate electrodes 130 are disposed on an upper surface.

The gate electrodes 130 may include a metal material, such as tungsten (W). In example embodiments, the gate electrodes 130 may include polycrystalline silicon or a metal silicide material. In example embodiments, the gate electrodes 130 may further include a diffusion barrier, for example, the diffusion barrier may include tungsten nitride (WN), tantalum nitride (TaN), titanium nitride (TiN), or a combination thereof.

The interlayer insulating layers 120 may be alternately disposed with the gate electrodes 130. The interlayer insulating layers 120 may also be spaced apart from each other in a direction perpendicular to an upper surface of the substrate 201 and may extend in the X-direction, similarly to the gate electrodes 130. The interlayer insulating layers 120 may include an insulating material, such as silicon oxide or silicon nitride. In each of the first to third stack structures GS1, GS2, and GS3, at least a portion of the interlayer insulating layers 120 may have different thicknesses. For example, a lowermost interlayer insulating layer 120L among the interlayer insulating layers 120 may have a relatively great thickness, and upper interlayer insulating layers 120_U may also have a relatively great thickness in each of the first to third stack structures GS1, GS2, and GS3. However, the relative thicknesses of the interlayer insulating layers 120 may be varied in example embodiments. The interlayer insulating layers 120 may include an insulating material such as silicon oxide or silicon nitride.

Each of the channel structures CH may form a memory cell string and the channel structures CH may be spaced apart from each other in rows and columns in the first region R1. The channel structures CH may be disposed to form a grid pattern on the x-y plane or may be disposed in a zigzag shape in one direction. The channel structures CH may have a columnar shape and may include regions having an inclined side surface having a width decreasing toward the substrate 201 depending on the aspect ratio. In example embodiments, at least a portion of the channel structures CH disposed at the end of the first region R1 may be dummy channel structures.

As illustrated in FIG. 3, each of the channel structures CH may include first to third channel portions CH1, CH2, and CH3 vertically stacked. The first to third channel portions CH1, CH2, and CH3 may extend through the first to third stack structures GS1, GS2, and GS3 of the gate structure GS, respectively. The channel structure CH may have a form in which a first channel portion CH1 and a second channel portion CH2 in an upper portion are connected to each other, and a second channel portion CH2 and a third channel portion CH3 in an upper portion are connected to each other. Each of the first to third channel portions CH1, CH2, and CH3 may have an inclined side surface such that a width decreases toward the substrate 201. The first to third channel portions CH1, CH2, and CH3 may have a form in which a width of an upper surface of a channel portion disposed in a lower portion may be greater than a width of a lower surface of a channel portion disposed in an upper portion in a region or on interfacial surface on which the channel portions are connected to each other.

Specifically, a first width W1 of an upper end of the first channel portion CH1 may be greater than a second width W2 of a lower end of the second channel portion CH2, and a third width W3 of an upper end of the second channel portion CH2 may be greater than a fourth width W4 of a lower end of the third channel portion CH3. In the first channel portion CH1, the first width W1 may be greater than the fifth width W5 of a lower end, in the second channel portion CH2, the third width W3 may be greater than the second width W2, and in the third channel portion CH3, the sixth width W6 of an upper end may be greater than the fourth width W4. The channel structure CH may have a width changing discontinuously at an interfacial surface between the first to third channel portions CH1, CH2, and CH3, and may have bent portions due to the difference in widths. However, in example embodiments, the number of channel portions stacked in the Z-direction in the channel structure CH may be varied.

Lower ends of the channel structures CH may be aligned with a lowermost interlayer insulating layer 120L. Upper ends of the channel structures CH may protrude to an upper portion interlayer insulating layer 120U of the third stack structure GS3. A height D1 by which an upper end of the channel structure CH protrudes may be varied in example embodiments.

Each of the channel structures CH may include a channel layer 140, a channel dielectric layer 145, a channel filling insulating layer 147, and a channel pad 149 disposed in the channel hole. The channel layer 140, the channel dielectric layer 145, and the channel filling insulating layer 147 may be connected to each other between the first to third channel portions CH1, CH2, and CH3.

The channel layer 140 may be formed in an annular shape surrounding the channel filling insulating layer 147 therein or may have a columnar shape such as a cylindrical shape or a prism shape without the channel filling insulating layer 147 in example embodiments. The channel layer 140 may include a semiconductor material such as polycrystalline silicon or single crystal silicon.

The channel dielectric layer 145 may be disposed between the gate electrodes 130 and the channel layer 140. The channel dielectric layer 145 may include a tunneling layer, a charge storage layer, and a blocking layer stacked in order from the channel layer 140. The tunneling layer may tunnel electric charge into the charge storage layer and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include, for example, silicon oxide (SiO₂), silicon nitride (Si₃N₄), silicon oxynitride (SiON), a high-ĸ dielectric material, or a combination thereof. In example embodiments, at least a portion of the channel dielectric layer 145 may extend in a horizontal direction along the gate electrodes 130.

The channel pad 149 may be disposed only on a lower end of a first channel portion CH1 in a lowermost portion. The channel pad 149 may include, for example, doped polycrystalline silicon.

An upper end of an uppermost third channel portion CH3 may be covered by a common source layer 105. The channel dielectric layer 145 may be removed from the common source layer 105 and the channel layer 140 may be exposed, and the exposed channel layer 140 may be in contact with the common source layer 105.

The common source layer 105 may extend horizontally on upper ends of the channel structures CH. The common source layer 105 may have a curvature, for example, along upper ends of the channel structures CH. The common source layer 105 may be electrically connected to the exposed channel layers 140 of the channel structures CH protruding to the upper interlayer insulating layer 120U as illustrated in FIG. 3. The common source layer 105 may function as a common source line of the semiconductor device 100. The common source layer 105 may be disposed only in the first region R1 and may not extend into the second region R2.

The common source layer 105 may include a conductive material, for example, polycrystalline silicon and/or a metal material. However, in some example embodiments, the shape of the common source layer 105 and the number of conductive layers included therein may be varied.

The first isolation regions MS may be disposed to extend in the X-direction by penetrating at least a portion of the gate electrodes 130. As illustrated in FIG. 1, the first isolation regions MS may be disposed in parallel to each other. A portion of the first isolation regions MS may extend along the first region R1 and the second region R2 as an integrated region, and the other portion may be disposed only in the second region R2. However, in example embodiments, the arrangement and the number of the first isolation regions MS are not limited to the example illustrated in FIG. 1. In some example embodiments, a portion of the first isolation regions MS may extend only from the first region R1 to a portion of the second region R2 or may be disposed intermittently in the first region R1 and the second region R2.

As illustrated in FIG. 2B, the first isolation regions MS may extend in the Z-direction by penetrating the gate electrodes 130. A lower end of the first isolation region MS may be positioned at a level the same as or lower than a level of the lower ends of the channel structures CH. An upper end of the first isolation region MS may be positioned at a level lower than a level of the upper ends of the channel structures CH. An upper end of the first isolation region MS may be coplanar with an upper surface of the upper interlayer insulating layer 120U, for example, but some example embodiments thereof is not limited thereto. In some example embodiments, an upper end of the first isolation region MS may protrude to the upper interlayer insulating layer 120U and may be positioned at a level the same as or similar to a level of the upper ends of the channel structures CH.

The first isolation region MS may have a shape of which a width decreases toward the common source layer 105. A width of the first isolation region MS in a lower portion may be greater than a width in an upper portion. For example, a side surface of the first isolation region MS may have a substantially constant slope such that the width may decrease continuously or have consecutive sections each with a constant slope and may not have a bent portion on the side surface. However, in some example embodiments, the first isolation regions MS may have a shape corresponding to the channel structures CH. In this case, for example, a level of a lower end of the first isolation region MS may be the same as the level of the lower ends of the channel structures CH. In example embodiments, “corresponding shape” may indicate the case in which the slope directions and the shapes including the bent portion may be the same or similar, and the dimensions such as the diameter and height may be the same or different. The first isolation regions MS may include an insulating material, for example, silicon oxide, silicon nitride, or silicon oxynitride.

The second isolation regions US may extend in the X-direction between the adjacent first isolation regions MS as illustrated in FIG. 1. The second isolation regions US may be disposed in the first region R1. The second isolation regions US may penetrate a portion of the gate electrodes 130, including a lower gate electrode 130L in a lowermost portion of the gate electrodes 130. The second isolation regions US may isolate, for example, three gate electrodes 130 from each other in the Y-direction as illustrated in FIG. 2B. The number of gate electrodes 130 isolated from each other by the second isolation regions US may be varied in example embodiments. The second isolation regions US may include an insulating material, for example, silicon oxide, silicon nitride, or silicon oxynitride.

The gate contact plugs 170 may be connected to end regions of the gate electrodes 130 in the gate pad regions GP of the second region R2. The gate contact plugs 170 may penetrate at least a portion of the first to fourth cell region insulating layers 192, 193, 194, and 196, and may be connected to the end regions of the gate electrodes 130, respectively. The gate contact plugs 170 may extend through the gate electrodes 130 above and below the end regions and may be connected to the studs 180. In some example embodiments, a portion of the gate contact plugs 170 may be positioned in a region other than the gate pad regions GP, for example, in the first region R1.

The gate contact plugs 170 may have a shape corresponding to the channel structures CH. Each of the gate contact plugs 170 may include first to third contact portions MC1, MC2, and MC3 stacked from a lower portion. The first to third contact portions MC1, MC2, and MC3 may penetrate first to third stack structures GS1, GS2, GS3 of the gate structure GS, respectively. Each of the first to third contact portions MC1, MC2, and MC3 may have a cylindrical shape of which a width decreases toward the substrate 201. Each of the first to third contact portions MC1, MC2, and MC3 may have a substantially constant slope.

As illustrated in FIG. 3, the first to third contact portions MC1, MC2, and MC3 may have a shape in which a width of an upper surface of a contact portion disposed in a lower portion is greater than a width of a lower surface of a contact portion disposed in an upper portion in a region or interfacial surface on which the contact portions are connected to each other. Accordingly, similarly to the channel structure CH, the contact plug 170 may have bent portions due to differences in widths on the interfacial surfaces between the first to third contact portions MC1, MC2, and MC3. The width may rapidly change in the bent portions, and the bent portions may include a region in which an external surface extends horizontally. As for the relative relationship between the widths of the first to third contact portions MC1, MC2, and MC3 on an upper end and a lower end, the description of the first to third channel portions CH1, CH2, and CH3 described above may be applied. However, a seventh width W7 of an upper end of the third contact portion MC3 may be greater than a sixth width W6 of an upper end of the third channel portion CH3. A diameter of the gate contact plug 170 may be greater than a diameter of the channel structure CH. In example embodiments, a comparison of a dimension, such as width or diameter, may indicate at least one of an average dimension, a dimension at the same level, or a maximum dimension, unless otherwise indicated.

Lower ends of the gate contact plugs 170 may be positioned at substantially the same level as lower ends of the channel structures CH. The lower ends of the gate contact plugs 170 and the lower ends of the channel structures CH may be aligned with the lowermost interlayer insulating layer 120L. For example, lower surfaces of the gate contact plugs 170 may be coplanar with lower surfaces of the channel structures CH and may be coplanar with a lower surface of the lowermost interlayer insulating layer 120L. The lower ends of the gate contact plugs 170 and the lower ends of the channel structures CH may be positioned in an insulating structure, and for example, in an insulating structure including the lowermost interlayer insulating layer 120L and the fifth cell region insulating layer 197. The lower ends of the gate contact plugs 170 and the lower ends of the channel structures CH may be in contact with and surrounded by the insulating structure, other than studs 180 connecting the ends. For example, when the lowermost interlayer insulating layer 120L is partially removed from a lower surface during the manufacturing process, the lower ends may be positioned in the fifth cell region insulating layer 197.

The upper ends of the gate contact plugs 170 may protrude from a third cell region insulating layer 194 and an upper interlayer insulating layer 120U of the third stack structure GS3 and may protrude to a fourth cell region insulating layer 196. The upper ends of the gate contact plugs 170 may be positioned at substantially the same level as the upper ends of the channel structures CH, but some example embodiments thereof is not limited thereto.

As illustrated in FIG. 3, the gate contact plug 170 may have a form extending horizontally from the end region of the gate electrode 130. The gate contact plug 170 may include a vertical extension portion extending in the Z-direction and a horizontal extension portion extending horizontally from the vertical extension portion and in contact with the gate electrode 130. A length from a side surface of the vertical extension portion to an end of the horizontal extension portion may be less than a length from a side surface of the vertical extension portion to external side surfaces of the contact insulating layers 160. The gate contact plug 170 may be electrically isolated from the gate electrodes 130 above and below the end region, that is, the gate electrodes 130 not connected to the gate contact plug 170, by the contact insulating layers 160.

The gate contact plugs 170 may include a conductive material, for example, at least one of tungsten (W), copper (Cu), aluminum (Al), and alloys thereof. In some example embodiments, the gate contact plugs 170 may include a barrier layer extending along a side surface and a bottom surface or may have an air gap therein.

The contact insulating layers 160 may be disposed to surround a side surface of each of the gate contact plugs 170 above and below each of the end regions. The contact insulating layers 160 may be spaced apart from each other in the Z-direction around each of the gate contact plugs 170. The contact insulating layers 160 may extend horizontally from a side surface of each of the gate contact plugs 170 by substantially the same length. The contact insulating layers 160 may be disposed at substantially the same level as the gate electrodes 130, respectively. The contact insulating layers 160 may include an insulating material, for example, silicon oxide, silicon nitride, or silicon oxynitride.

The through-contact plug THV may be disposed to penetrate the first to third cell region insulating layers 192, 193, and 194 in the third region R3. The through-contact plug THV may electrically connect the second interconnection structure of an upper portion to the first semiconductor structure S1. The through-contact plug THV may have a shape corresponding to the gate contact plug 170 and may have a diameter the same as or greater than a diameter of the gate contact plug 170.

A lower end of the through-contact plug THV may be positioned at substantially the same level as the lower ends of the gate contact plugs 170 and the lower ends of the channel structures CH. Accordingly, the aforementioned description of the lower ends of the gate contact plugs 170 may be applied to the lower end of the through-contact plug THV. The through-contact plug THV may include at least one of a conductive material, for example, tungsten (W), copper (Cu), aluminum (Al), or alloys thereof.

The first to third cell region insulating layers 192, 193, and 194 may be disposed to cover the first to third stack structures GS1, GS2, and GS3, respectively. The fourth cell region insulating layer 196 may be disposed on the third stack structure GS3, and the fifth cell region insulating layer 197 may be disposed below the first stack structure GS1. The first to fifth cell region insulating layers 192, 193, 194, 196, and 197 may include at least one of an insulating material, for example, silicon oxide, silicon nitride, or silicon carbide, and in example embodiments, at least one of the first to fifth cell region insulating layers 192, 193, 194, 196, and 197 may include a plurality of insulating layers. When the first to fifth cell region insulating layers 192, 193, 194, 196, and 197 include the same material as a material of the interlayer insulating layers 120, the interfacial surfaces with the interlayer insulating layers 120 may not be distinct.

Studs 180, first cell contact plugs 185, and first cell interconnection lines 187 may form a second interconnection structure electrically connected to memory cells in the second semiconductor structure S2. The studs 180 may be connected to lower ends of channel structures CH, lower ends of gate contact plugs 170, and a lower end of a through-contact plug THV and may be electrically connected to the channel structures CH and the gate electrodes 130. The first cell contact plugs 185 may be connected to a lower end of the studs 180, and the first cell interconnection lines 187 may be connected to lower ends of the first cell contact plugs 185. Among the first cell interconnection lines 187, the first cell interconnection lines 187 disposed below the channel structures CH may be bitlines. In example embodiments, the number of plugs and interconnection lines which may be included in the second interconnection structure may be varied. Each of the studs 180, the first cell contact plugs 185, and the first cell interconnection lines 187 may include a metal, for example, tungsten (W), copper (Cu), aluminum (Al), or the like.

The second cell contact plugs 188 and the second cell interconnection lines 189 may be disposed on the channel structures CH and the gate contact plugs 170. The second cell contact plugs 188 may be connected to upper ends of the common source layer 105, the gate contact plugs 170, and the through-contact plug THV, and the second cell interconnection lines 189 may be connected to upper ends of the second cell contact plugs 188.

Each of the second cell contact plugs 188 and the second cell interconnection lines 189 may include a metal, for example, tungsten (W), copper (Cu), aluminum (Al), or the like.

The second bonding vias 195 and the second bonding pads 198 may be disposed below the first cell interconnection lines 187. The second bonding vias 195 may connect the first cell interconnection lines 187 to the second bonding pads 198, and the second bonding pads 198 may be bonded to the first bonding pads 298 of the first semiconductor structure S1. The second bonding insulating layer 199 may be bonded to the first bonding insulating layer 299 of the first semiconductor structure S1. The second bonding vias 195 and the second bonding pads 198 may include a conductive material, for example, copper (Cu). The second bonding insulating layer 199 may include at least one of, for example, SiO, SiN, SiCN, SiOC, SiON, or SiOCN.

The first and second semiconductor structures S1 and S2 may be bonded to each other by bonding between the first bonding pads 298 and the second bonding pads 198 and by bonding between the first bonding insulating layer 299 and the second bonding insulating layer 199. The bonding between the first bonding pads 298 and the second bonding pads 198 may be, for example, copper (Cu)-copper (Cu) bonding, and the bonding between the first bonding insulating layer 299 and the second bonding insulating layer 199 may be, for example, dielectric-dielectric bonding such as SiCN-SiCN bonding. The first and second semiconductor structures S1 and S2 may be bonded to each other by hybrid bonding including copper (Cu)-copper (Cu) bonding and dielectric-dielectric bonding.

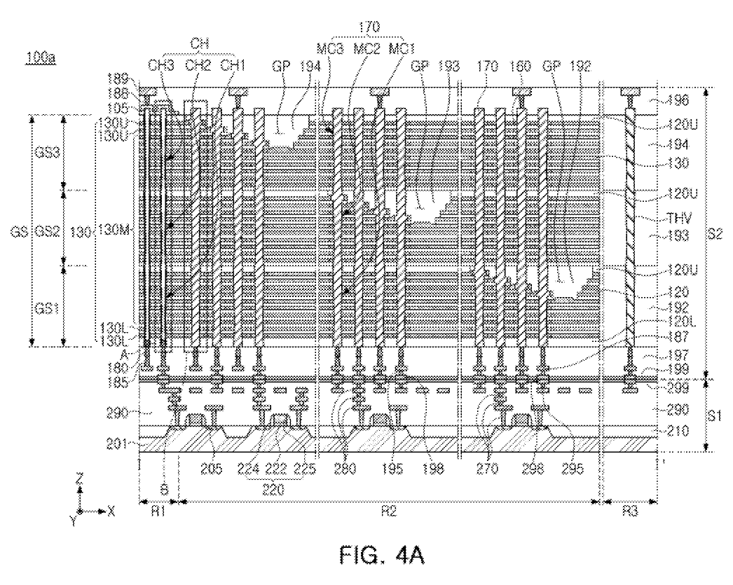

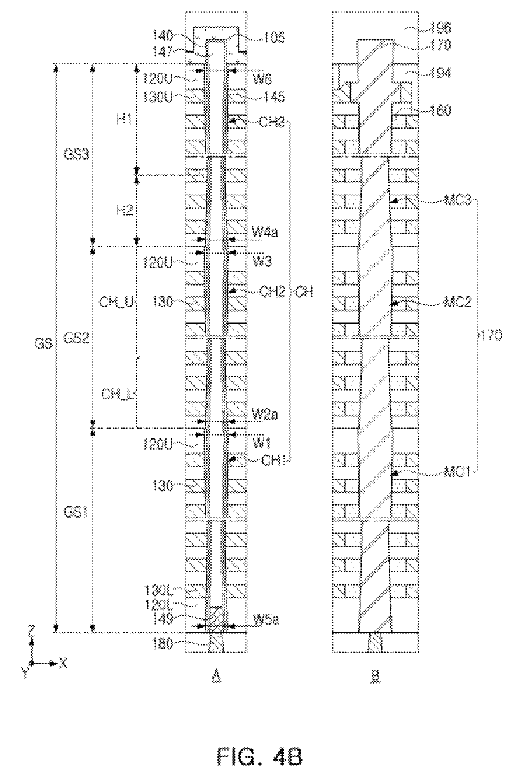

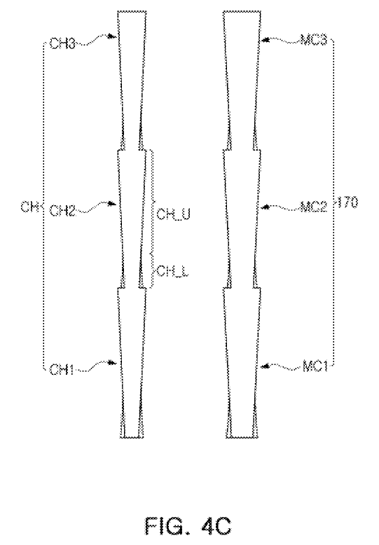

FIGS. 4A, 4B, and 4C are a cross-sectional diagram, an enlarged diagram, and a view illustrating a semiconductor device according to example embodiments. FIGS. 4A and 4B illustrate regions corresponding to FIGS. 2A and 3, respectively, and FIG. 4C is a view illustrating the shapes of the channel structure CH and the gate contact plug 170.

Referring to FIGS. 4A, 4B, and 4C, in the semiconductor device 100a, the shape of the channel structures CH and the gate contact plugs 170 may be different from the example embodiments in FIGS. 2A, 2B and 3. As indicated by the dotted line in FIG. 4C, the channel structures CH and the gate contact plugs 170 in the example embodiments may have a shape in which widths of lower regions are widened as compared to the example embodiments in FIGS. 2A, 2B and 3.

Each of the first to third channel portions CH1, CH2, and CH3 may include an upper region CH_U and a lower region CH_L. The upper region CH_U may have an inclined side surface such that a width thereof decreases toward the substrate 201. The lower region CH_L may have an inclined side surface such that a width thereof increases toward the substrate 201. The lower regions CH_L may be adjacent to interfacial surfaces between the first to third channel portions CH1, CH2, and CH3 and a lower end of the channel structure CH, may have a widened width. Accordingly, the channel structures CH in the example embodiments may have a shape in which the region of which an external surface extends horizontally is relatively shortened or omitted in the bent portions between the first to third channel portions CH1, CH2, and CH3. Even in this case, the width of the channel structures CH may change to a different tendency, for example, to an opposite slope, between the first to third channel portions CH1, CH2, and CH3.

A height H1 of the upper region CH_U may be greater than a height H2 of the lower region CH_L. However, in example embodiments, the height H2 of the lower region CH_L may be varied. In some example embodiments, the lower region CH_L may have a curved side surface rather than a linear line. In some example embodiments, a boundary between the upper region CH_U and the lower region CH_L may not be clearly distinct.

A first width W1 of an upper end of a first channel portion CH1 may be the same as or greater than a second width W2a of a lower end of a second channel portion CH2, and a third width W3 of an upper end of the second channel portion CH2 may be the same as or greater than a fourth width W4a of a lower end of a third channel portion CH3. In the first channel portion CH1, the first width W1 may be the same as or greater than a fifth width W5a of a lower end; in the second channel portion CH2, the third width W3 may be the same as or greater than the second width W2a; and in the third channel portion CH3, the sixth width W6 of an upper end may be the same as or greater than the fourth width W4a. In some example embodiments, the first width W1 may be less than the fifth width W5a, the third width W3 may be less than the second width W2a, and the sixth width W6 may be less than the fourth width W4a.

The gate contact plugs 170 may have a shape corresponding to the channel structures CH. In the gate contact plugs 170, each of the first to third contact portions MC1, MC2, and MC3 may include an upper region of which a width decreases toward the substrate 201 and a lower region of which a width increases toward the substrate 201. In the first to third contact portions MC1, MC2, and MC3, the relative relationship of the widths at the upper end and the lower end may be applied in the same manner as the description for the first to third channel portions CH1, CH2, and CH3 described above.

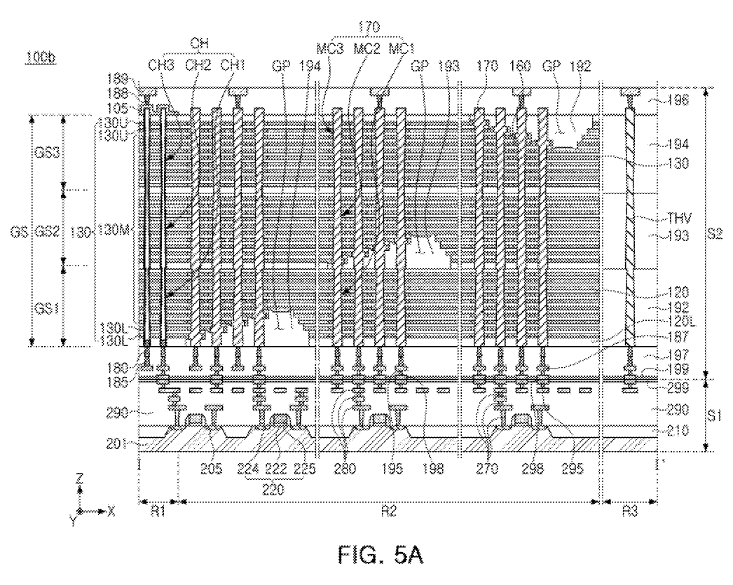

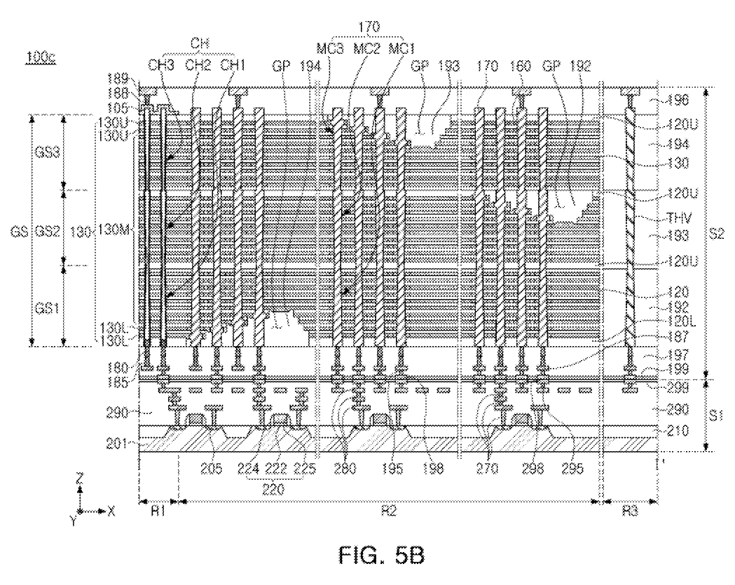

FIGS. 5A and 5B are cross-sectional views illustrating a semiconductor device according to example embodiments, illustrating a region corresponding to FIG. 2A.

Referring to FIGS. 5A and 5B, in semiconductor devices 100b and 100c, the shapes of the channel structures CH and the gate contact plugs 170 may be different from the example embodiments in FIGS. 2A, 2B and 3. Also, the shapes of the first to third stack structures GS1, GS2, and GS3 included in the gate structure GS may also be different from the example embodiments in FIGS. 2A, 2B and 3.

As illustrated in FIG. 5A, in the semiconductor device 100b, widths of lower ends of the first channel portion CH1 and the first contact portion MC1 may be greater than a width of an upper end, widths of lower ends of the second channel portion CH2 and the second contact portion MC2 may be greater than a width of an upper end, and width of upper ends of the third channel portion CH3 and the third contact portion MC3 may be greater than a width of a lower end. The first and second channel portions CH1 and CH2 and the first and second contact portions MC1 and MC2 may have inclined side surfaces such that widths thereof increase toward the substrate 201, and the third channel portion CH3 and the third contact portion MC3 may have inclined side surfaces such that widths thereof decrease toward the substrate 201. The through-contact plug THV may also have a shape corresponding to the channel structures CH and the gate contact plugs 170.

In the example embodiments, the gate pad regions GP may be disposed in the order of the first stack structure GS1, the second stack structure GS2, and the third stack structure GS3 in the X-direction. The gate pad regions GP may have a shape removed from a lower portion by a predetermined depth in the first and second stack structures GS1 and GS2 and may have a shape removed from an upper portion by a predetermined depth in the third stack structure GS3. However, the position and the shape of the gate pad regions GP may be varied in the example embodiments.

As illustrated in FIG. 5B, in the semiconductor device 100c, widths of lower ends of the first channel portion CH1 and the first contact portion MC1 may be greater than a width of an upper end, widths of upper ends of the second channel portion CH2 and the second contact portion MC2 may be greater than a width of a lower end, and widths of upper ends of the third channel portion CH3 and the third contact portion MC3 may be greater than a width of a lower end. The first channel portion CH1 and the first contact portion MC1 may have inclined side surfaces such that widths thereof increase toward the substrate 201, and the second and third channel portions CH2 and CH3 and the second and third contact portions MC2 and MC3 may have inclined side surfaces such that widths thereof decrease toward the substrate 201. The through-contact plug THV may also have a shape corresponding to the channel structures CH and the gate contact plugs 170.

In the example embodiments, the gate pad regions GP may be disposed in the order of the first stack structure GS1, the third stack structure GS3, and the second stack structure GS2 in the X-direction. The gate pad regions GP may have a shape removed from a lower portion by a predetermined depth in the first stack structure GS1, and the second and third stack structures GS2 and GS3 may have a shape removed from an upper portion by a predetermined depth in the second and third stack structures GS2 and GS3. However, the arrangement position and the shape of the gate pad regions GP may be varied in the example embodiments.

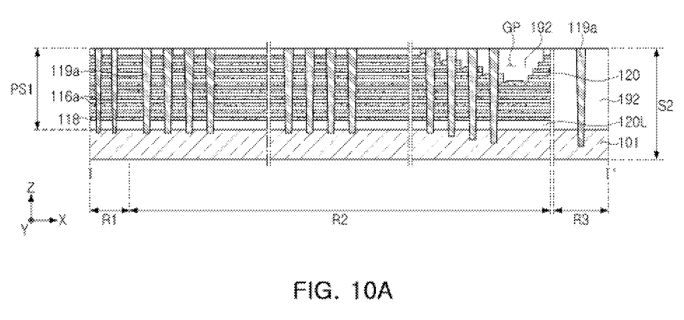

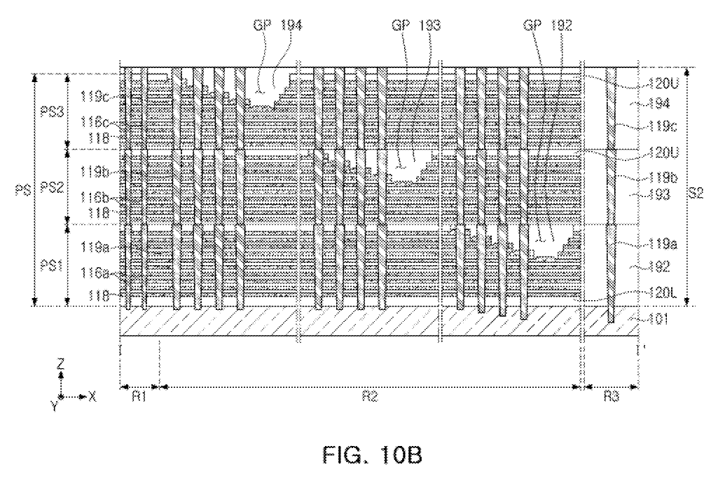

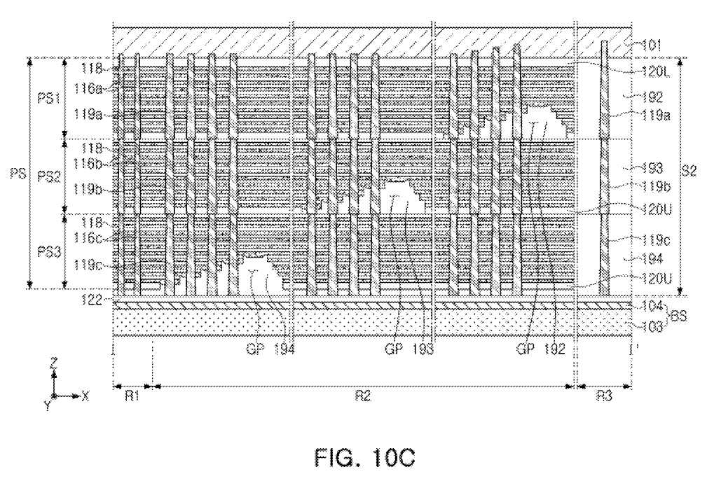

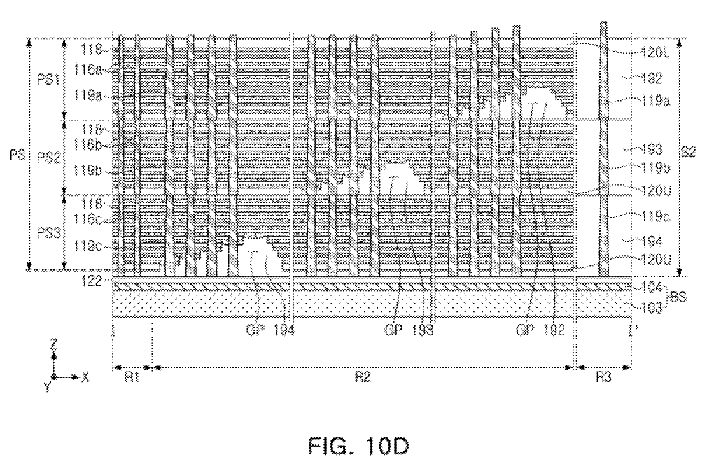

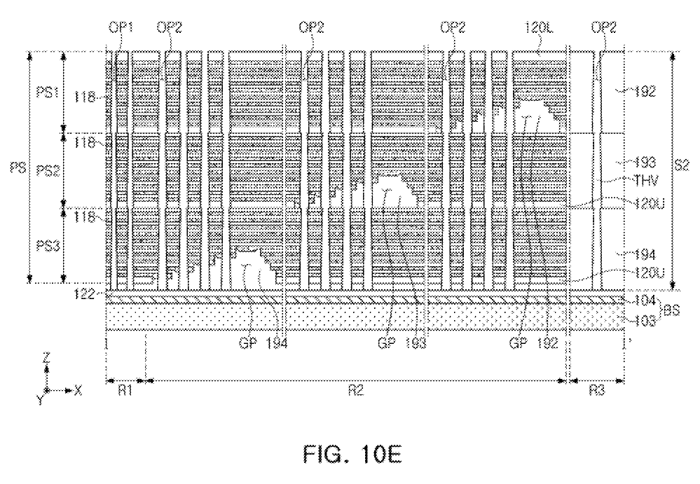

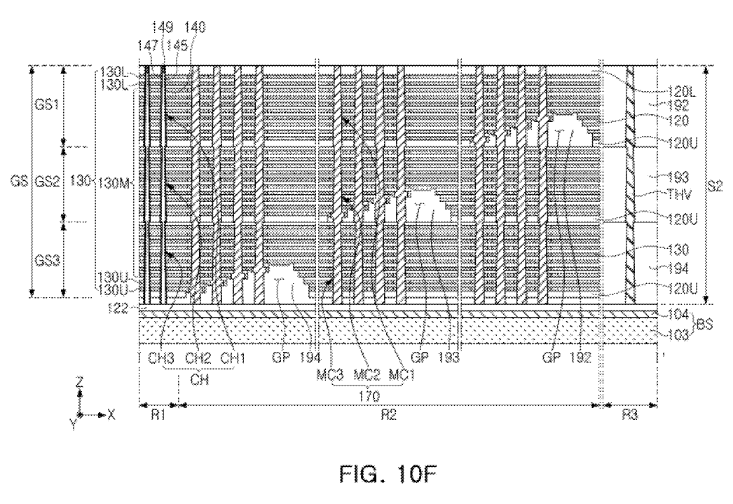

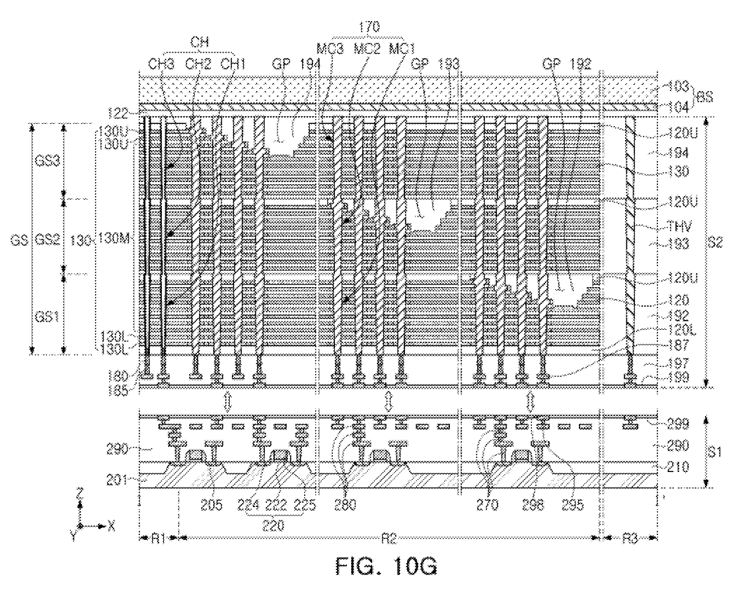

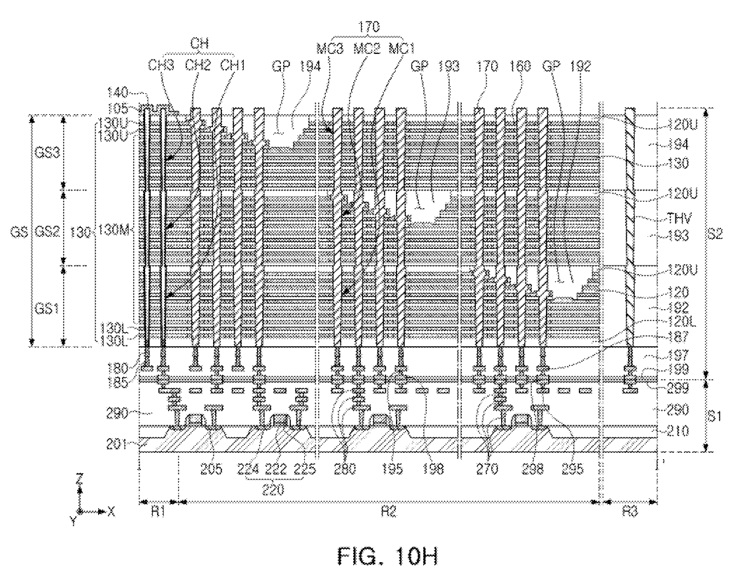

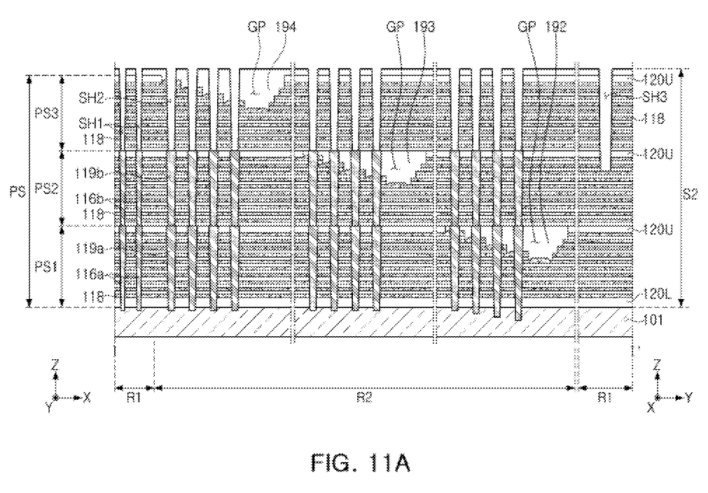

The manufacturing processes of the example embodiments in FIGS. 5A and 5B may be different from those of the example embodiments in FIGS. 2A, 2B and 3. The example embodiments in FIGS. 2A, 2B and 3 may have structures in which the reverting and bonding process described below with reference to FIG. 10C is performed after the first to third mold structures PS1 and PS2, and PS3 are formed. Differently from the above example, the example embodiments in FIGS. 5A and 5B may be structures in which the reverting and bonding process is performed after the first mold structure PS1 is formed and after the first and second mold structures PS1 and PS2 are formed.

In some example embodiments, as in the example embodiments in FIGS. 4A and 4B, in the example embodiments in FIGS. 5A and 5B, the first to third channel portions CH1, CH2, and CH3 and the first to third contact portions MC1, MC2, and MC3 may have a shape in which the widths thereof are widened in the end region having a relatively narrow width.

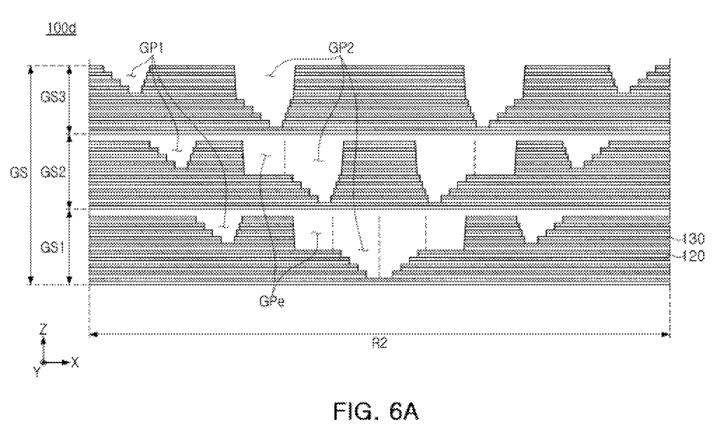

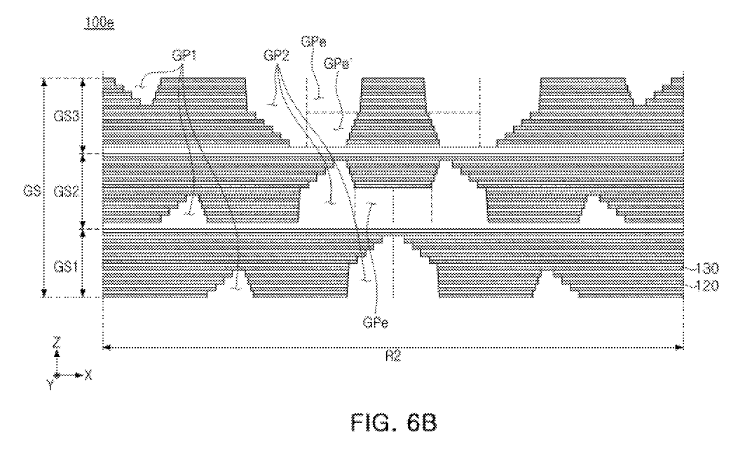

FIGS. 6A and 6B are cross-sectional views illustrating a semiconductor device according to example embodiments, only illustrating a gate structure GS in a second region R2.

Referring to FIG. 6A, in a semiconductor device 100d, the gate structure GS may include first and second gate pad regions GP1 and GP2 and extended gate pad regions GPe. The gate electrodes 130 may form a step structure in the first and second gate pad regions GP1 and GP2, and the gate contact plugs 170 (see FIG. 2A) may be connected to the gate electrodes 130 in the first and second gate pad regions GP1 and GP2 and may extend vertically.

In the first gate pad regions GP1, the gate electrodes 130 may be removed from an upper portion by a predetermined depth and may form step structures having a staircase shape. For example, the gate pad regions GP in FIG. 2A may correspond to the first gate pad regions GP1 in the example embodiments.

The second gate pad regions GP2 may be disposed to extend deeper than the first gate pad regions GP1. In each of the first to third stack structures GS1, GS2, and GS3, the gate electrodes 130 below the first gate pad regions GP1 may form a step structure in the second gate pad regions GP2.

The extended gate pad regions GPe may be disposed below the second gate pad regions GP2. The extended gate pad regions GPe may be disposed adjacent to the interfacial surfaces of the first to third stack structures GS1, GS2, and GS3, thereby preventing punching of the gate contact plugs 170 disposed in the second gate pad regions GP2 in an upper portion due to misalignment, and thus preventing a bridge defect.

For example, the first gate pad regions GP1 may be disposed in the third stack structure GS3, the second stack structure GS2, and the first stack structure GS1 in order in the X-direction, and the second gate pad regions GP2 may be disposed in the third stack structure GS3, the second stack structure GS2, and the first stack structure GS1 in order in the X-direction. However, the arrangement shape, arrangement order, and depth of the first and second gate pad regions GP1 and GP2 may be varied.

Referring to FIG. 6B, in a semiconductor device 100e, the arrangement shape of the second gate pad regions GP1 and GP2 and the extended gate pad regions GPe may be different from the example embodiments in FIG. 6A. Also, the gate structure GS may further include additional extended gate pad regions GPe’.

In the example embodiments in FIG. 6B, the reverting and bonding process described above is performed after the first mold structure PS1 is formed, and may be, for example, a structure formed by the same process as the example embodiments in FIG. 5A. In this case, by adjusting the positions of the second gate pad regions GP1 and GP2 and further disposing additional extended gate pad regions GPe’, a bridge defect between the gate contact plugs 170, or the like, may be prevented. In example embodiments, the arrangement position and shape of the gate pad regions may be changed depending on the order in which the reverting and bonding process is performed, and the arrangement and additional shape of the extended gate pad regions may be varied.

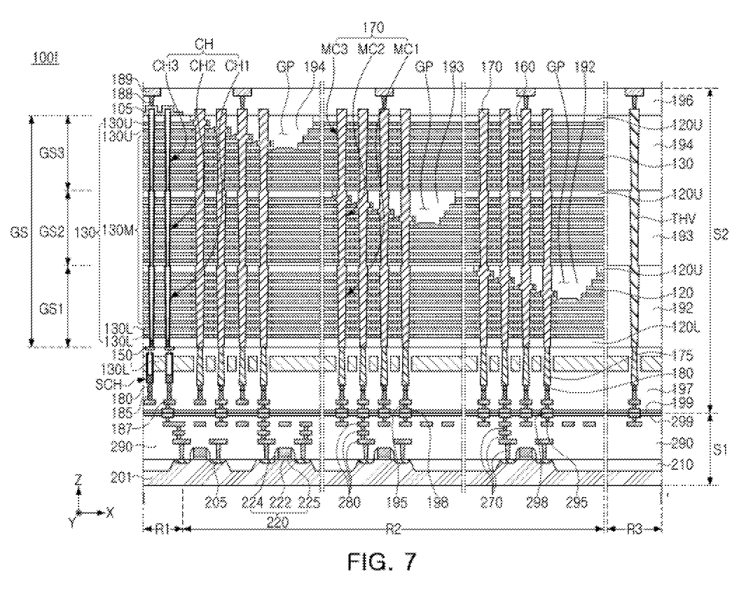

FIG. 7 is a cross-sectional view illustrating a semiconductor device according to example embodiments, illustrating a region corresponding to FIG. 2A.

Referring to FIG. 7, in a semiconductor device 100f, the second semiconductor structure S2 may further include string channel structures SCH connected to channel structures CH and lower contacts 175 connected to gate contact plugs 170.

Among the gate electrodes 130, a lowermost gate electrode 130L’ may be disposed to have a relatively thick thickness. The string channel structures SCH may be disposed to penetrate the lowermost gate electrode 130L’, and the channel structures CH may be disposed to penetrate the gate electrodes 130 other than the lowermost gate electrode 130L’. The lowermost gate electrode 130L’ may include a conductive material, for example, polycrystalline silicon.

The string channel structures SCH may be connected to the channel structures CH, respectively. The string channel structures SCH may be disposed below the channel structures CH, respectively, and may be shifted from the channel structures CH in the horizontal direction, but example embodiments thereof are not limited thereto. The string channel structures SCH may have an inclined side surface such that a width thereof increases toward the substrate 201.

The internal structure of the string channel structures SCH may correspond to the channel structures CH, and accordingly, the stacking form of the layers may be the same. The string channel structures SCH may include an upper channel layer, an upper channel dielectric layer, an upper channel filling insulating layer, and an upper channel pad disposed in the string channel hole and may further include a connection pad 150 disposed on the string channel hole. The upper channel layer may be connected to the connection pad 150 in a lower portion and may be electrically connected to the channel layer 140 (see FIG. 3) of the channel structure CH through the connection pad 150.

As for materials of the upper channel layer, the upper channel dielectric layer, the upper channel filling insulating layer, and the upper channel pad, the descriptions of the channel layer 140, the channel dielectric layer 145, the channel filling insulating layer 147, and the channel pad 149 described above with reference to FIG. 3 may be applied. The connection pad 150 may include a conductive material, for example, polycrystalline silicon.

The lower contacts 175 may connect the gate contact plugs 170 to the studs 180 below the gate contact plugs 170. The lower contacts 175 may include a conductive material, for example, a metal material. The lower contacts 175 may have an inclined side surface such that a width of a lower end is greater than a width of an upper end.

The structures of the lowermost gate electrode 130L’, the string channel structures SCH, and the lower contacts 175 in the example embodiments may also be applied to other example embodiments.

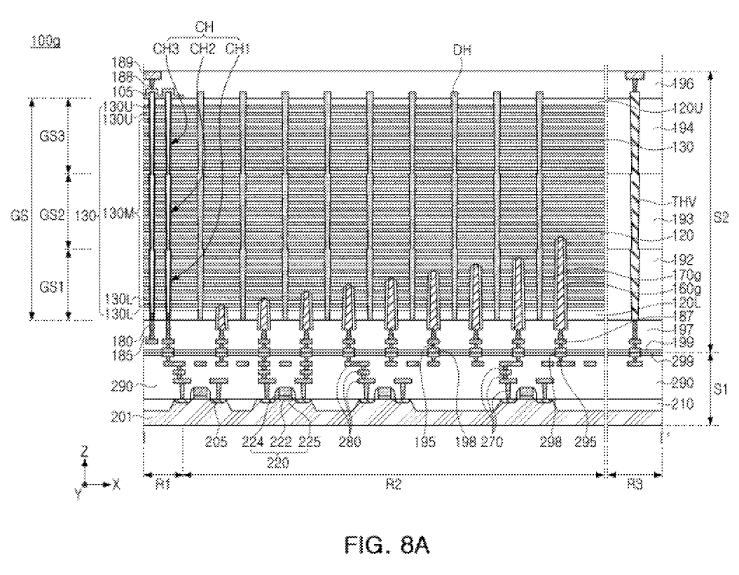

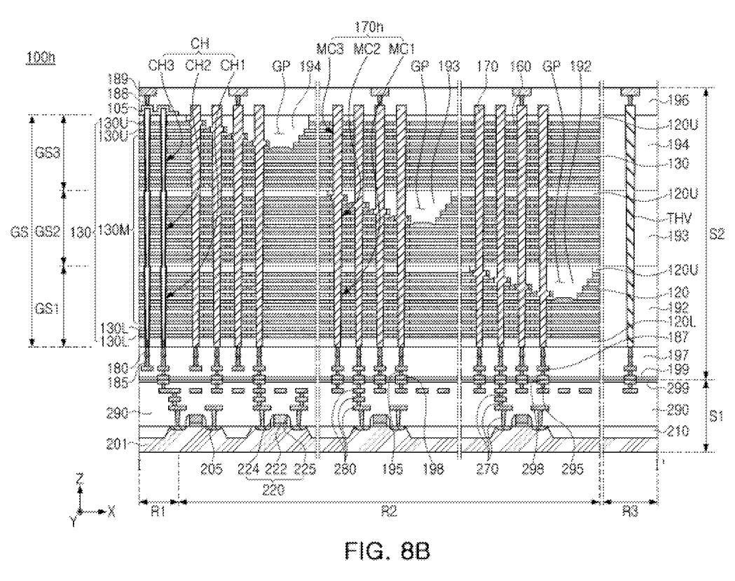

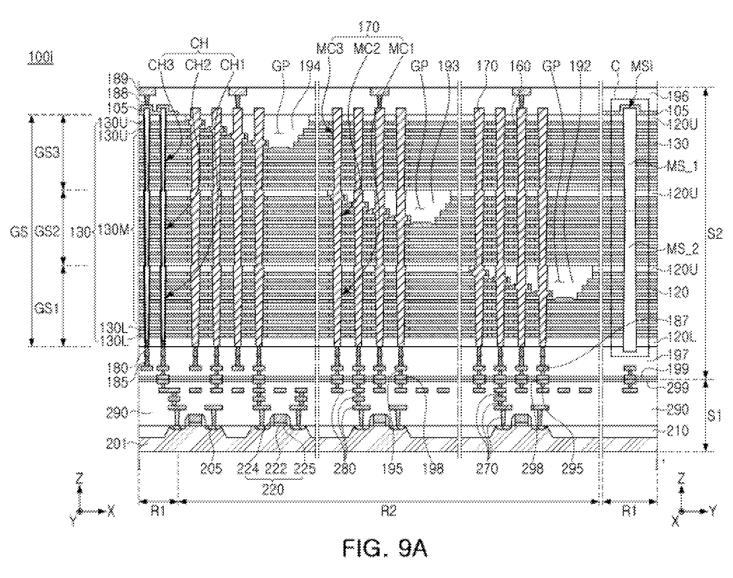

FIGS. 8A and 8B are cross-sectional views illustrating a semiconductor device according to example embodiments, illustrating a region corresponding to FIG. 2A.

Referring to FIG. 8A, in the second semiconductor structure S2 of a semiconductor device 100g, the gate structure GS may not include the gate pad region GP, and the gate contact plugs 170g may extend vertically from below the gate structure GS to the gate electrode 130 electrically connected by penetrating the gate structure GS. Also, the second semiconductor structure S2 may further include dummy vertical structures DH disposed in the second region R2.

The gate electrodes 130 may be stacked vertically and spaced apart from each other in the first and second regions R1 and R2. The gate electrodes 130 may not form a staircase shape in the first and second regions R1 and R2 and may have a form in which the entire gate electrodes 130 are vertically stacked. The gate electrodes 130 may extend to the same length in the horizontal direction in the first and second regions R1 and R2. Accordingly, the gate contact plugs 170g, other than the gate contact plug 170g connected to the lowermost gate electrode 130L among the gate contact plugs 170g, may extend through at least one gate electrode 130 upwardly. The ends of the gate electrodes 130 in the X-direction may be positioned, for example, at a boundary between the second region R2 and the third region R3.

The contact insulating layers 160g may be disposed on side surfaces of the gate contact plugs 170g, respectively. The contact insulating layers 160g may electrically isolate the gate contact plugs 170g from the gate electrodes 130 through which the gate contact plugs 170g penetrate. The contact insulating layers 160g may extend along the side surfaces of the gate contact plugs 170g to lower surfaces of the gate electrodes 130 connected to the gate contact plugs 170g. The contact insulating layers 160g may expose lower surfaces of the gate contact plugs 170g.

Dummy vertical structures DH may be disposed between or around the gate contact plugs 170g in the second region R2 and may be spaced apart from each other while forming rows and columns in the plan view. In some example embodiments, a portion of the dummy vertical structures DH may be in contact with the gate contact plugs 170g. The dummy vertical structures DH may have a pillar shape penetrating the gate electrodes 130 and may have a shape corresponding to the channel structures CH. The dummy vertical structures DH may have bent portions corresponding to the first to third channel portions CH1, CH2, and CH3. In some example embodiments, the dummy vertical structures DH may include regions protruding from side surfaces toward the gate electrodes 130. The dummy vertical structures DH may include an insulating material, such as silicon oxide, silicon nitride, or silicon oxynitride. The dummy vertical structures DH in some example embodiments may also be disposed adjacent to the gate contact plugs in other example embodiments.

Referring to FIG. 8B, in the second semiconductor structure S2 of a semiconductor device 100h, the gate contact plugs 170h may have a shape different from that of the channel structures CH. The gate contact plugs 170h may extend from an upper end to a lower end with a substantially constant slope without a bent portion at interfacial surfaces between the first to third stack structures GS1, GS2, and GS3. The gate contact plugs 170h may have a shape in which a width decreases toward the substrate 201. The upper ends of the gate contact plugs 170h may be positioned at a level higher than a level of the upper ends of the channel structures CH.

In some example embodiments, the contact holes in which the gate contact plugs 170h are disposed may be formed in a process different from the process of forming channel holes in which the channel structures CH are disposed, and accordingly, the gate contact plugs 170h may not have a shape corresponding to the channel structures CH. In some example embodiments, the gate contact plugs 170h may have a shape in which a width increases toward the substrate 201 while being disposed upside down. In this case, the lower ends of the gate contact plugs 170h may be positioned at a level lower than a level of the lower ends of the channel structures CH.

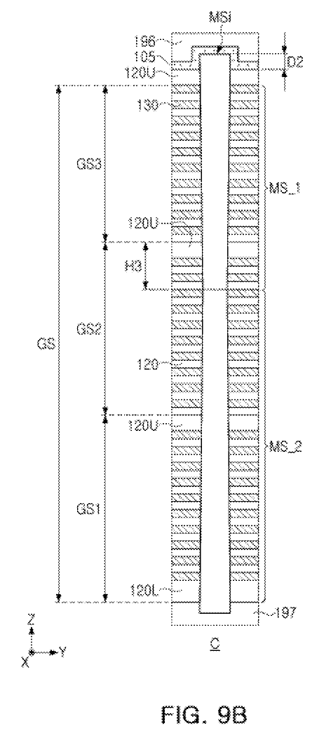

FIGS. 9A and 9B are cross-sectional and enlarged views illustrating a semiconductor device according to example embodiments. FIG. 9B is an enlarged view illustrating region “C” in FIG. 9A.

Referring to FIGS. 9A and 9B, in a semiconductor device 100i, the shape of the first isolation region MSi may be different from the example embodiments in FIG. 2B. To help understanding, in FIG. 9A, a cross-sectional surface in the Y-direction for the first isolation region MSi is illustrated together instead of the third region R3 in FIG. 2A. The shape of the through-contact plug THV disposed in the third region R3 in FIG. 2A may also be applied to the example embodiments.

As illustrated in FIG. 9B, the first isolation region MSi may include a first portion MS_1 having a width decreasing from a common source layer 105 toward a substrate 201, and a second portion MS_2 connected to the first portion MS_1 below the first portion MS_1 and having a width increasing toward the substrate 201. A side surface of each of the first portion MS_1 and the second portion MS_2 may have a substantially constant slope such that a width decreases continuously or continuously in consecutive portions, and may not have a bent portion in the side surface.

A lower end of the first portion MS_1 may be positioned in the second stack structure GS2, for example, positioned at an upper region of the second stack structure GS2. A height H3 of the first portion MS_1 extending into the second stack structure GS2 may be varied in example embodiments. In some example embodiments, the height H3 may be zero, and in this case, a lower end of the first portion MS_1 may be positioned at an interfacial surface between the first stack structure GS1 and the second stack structure GS2.

A lower end of the first isolation region MSi may be positioned at a level lower than a level of the lower ends of the channel structures CH. An upper end of the first isolation region MSi may be positioned at a level the same as or lower than a level of the upper ends of the channel structures CH. For example, an upper end of the first isolation region MSi may be positioned at substantially the same level as the upper ends of the channel structures CH and the upper ends of the gate contact plugs 170. In some example embodiments, depending on the process of the common source layer 105, an upper end of the first isolation region MSi may be coplanar with, for example, an upper surface of the upper interlayer insulating layer 120U.

FIGS. 10A, 10B, 10C, 10D, 10E, 10F, 10G and 10H are cross-sectional views illustrating a semiconductor device according to example embodiments, each illustrating a cross-sectional surface corresponding to FIG. 2A.

Referring to FIG. 10A, a process of manufacturing the second semiconductor structure S2 may be started. Sacrificial insulating layers 118 and interlayer insulating layers 120 may be alternately stacked on a base substrate 101, thereby forming a first mold structure PS1, and first channel sacrificial layers 116a and first contact sacrificial layers 119a penetrating the first mold structure PS1 may be formed.

The base substrate 101 may be removed through a subsequent process, and may be, for example, a semiconductor substrate such as undoped silicon (Si).

At least a portion of the sacrificial insulating layers 118 may be replaced with gate electrodes 130 (see FIG. 2A) through a subsequent process. The sacrificial insulating layers 118 may be formed of a material different from that of the interlayer insulating layers 120 and may be formed of a material etched with etch selectivity under specific etch conditions with respect to the interlayer insulating layers 120. For example, the interlayer insulating layer 120 may be formed of at least one of silicon oxide or silicon nitride, and the sacrificial insulating layers 118 may be formed of a material different from that of the interlayer insulating layer 120 selected from among silicon, silicon oxide, silicon carbide and silicon nitride. In example embodiments, thicknesses of the interlayer insulating layers 120 may not be the same as described above with reference to FIGS. 1, 2A, 2B and 3. For example, the upper interlayer insulating layers 120U and the lowermost interlayer insulating layer 120L may have relatively great thicknesses. The number of the interlayer insulating layers 120 and the sacrificial insulating layers 118 may be varied from the illustrated example.

The first mold structure PS1 may include a gate pad region GP. The gate pad region GP may be formed by repeatedly performing a photolithography process and an etching process for the sacrificial insulating layers 118 and the interlayer insulating layers 120. The gate pad regions GP may be formed in the second region R2 and may be formed to include a region in which the sacrificial insulating layers 118 in an upper portion extend a shorter length than the sacrificial insulating layers 118 in a lower portion. In the gate pad region GP, step structures may be formed such that an upper surface and an end of a plurality of sacrificial insulating layers 118 may be exposed upwardly. The sacrificial insulating layers 118 may be further formed on the step structure of the gate pad regions GP, such that the sacrificial insulating layers 118 positioned in an uppermost portion in each region may have a relatively great thickness.

The first cell region insulating layer 192 covering the first mold structure PS1 may be formed. The first channel sacrificial layers 116a may be formed in positions corresponding to the channel structures CH (see FIG. 2A) in the first region R1. The first contact sacrificial layers 119a may be formed in positions corresponding to the gate contact plugs 170 (see FIG. 2A) and the through-contact plug THV in the second region R2. The first channel sacrificial layers 116a and the first contact sacrificial layers 119a may be formed simultaneously and may be collectively referred to as first vertical sacrificial layers herein.

The first channel sacrificial layers 116a and the first contact sacrificial layers 119a may be formed by forming first holes to penetrate the first mold structure PS1, depositing a sacrificial layer material in the first holes, and performing a planarization process. The first holes may extend into the base substrate 101, and lengths by which the first holes extend into the base substrate 101 may be different from each other. For example, the first holes formed in positions corresponding to the gate pad regions GP and the through-contact plug THV may penetrate less the sacrificial insulating layers 118, and thus, the length of extension into the base substrate 101 may be relatively deep. The first channel sacrificial layers 116a and the first contact sacrificial layers 119a may include, for example, polycrystalline silicon, a carbon-based material, or a metal material.

In the example embodiments in FIG. 7, in this process, the first channel sacrificial layers 116a may be further formed in regions corresponding to the dummy vertical structures DH.

Referring to FIG. 10B, a second mold structure PS2, second channel sacrificial layers 116b, and the second contact sacrificial layers 119b may be formed on a first mold structure PS1, and a third mold structure PS3, third channel sacrificial layers 116c, and the third contact sacrificial layers 119c may be formed on the second mold structure PS2.

The second and third mold structures PS2 and PS3 may be manufactured by alternately stacking the sacrificial insulating layers 118 and the interlayer insulating layers 120 and forming a gate pad region GP in the same manner as the first mold structure PS1. Accordingly, a mold structure MOS including the first to third mold structures PS1 and PS2, and PS3 may be formed.

A second cell region insulating layer 193 covering the second mold structure PS2 may be formed, and second channel sacrificial layers 116b and second contact sacrificial layers 119b may be formed. The second channel sacrificial layers 116b may be formed to be connected to the first channel sacrificial layers 116a, respectively, and the second contact sacrificial layers 119b may be formed to be connected to the first contact sacrificial layers 119a, respectively. The second channel sacrificial layers 116b and the second contact sacrificial layers 119b may be formed simultaneously and may be collectively referred to as second vertical sacrificial layers herein. The second channel sacrificial layers 116b and the second contact sacrificial layers 119b may be formed by forming second holes and depositing the same material as the first channel sacrificial layers 116a and the first contact sacrificial layers 119a into the second holes.

A third cell region insulating layer 194 covering the third mold structure PS3 may be formed, and third channel sacrificial layers 116c and third contact sacrificial layers 119c may be formed. The third channel sacrificial layers 116c may be formed to be connected to the second channel sacrificial layers 116b, respectively, and the third contact sacrificial layers 119c may be formed to be connected to the second contact sacrificial layers 119b, respectively. The third channel sacrificial layers 116c and the third contact sacrificial layers 119c may be formed simultaneously and may be collectively referred to as third vertical sacrificial layers herein. The third channel sacrificial layers 116c and the third contact sacrificial layers 119c may be formed by forming third holes and depositing the same material as the first and second channel sacrificial layers 116a and 116b and the first and second contact sacrificial layers 119a and 119b into the third holes.

In the example embodiments in FIG. 8B, the first to third contact sacrificial layers 119a, 119b, and 119c may not be formed, the first to third channel sacrificial layers 116a, 116b, and 116c may be formed, the contact holes may be formed separately, and a single contact sacrificial layer may be deposited to each of the contact holes.

Referring to FIG. 10C, the structure may be bonded to the substrate for bonding structure BS by reverting the structure.

The substrate for bonding structure BS may include a substrate for bonding 103 and a first bonding dielectric layer 104. The substrate for bonding 103 may be removed through a subsequent process and may be, for example, a semiconductor substrate such as undoped silicon (Si). The first bonding dielectric layer 104 may be a layer for dielectric-dielectric bonding and may include, for example, at least one of SiO, SiN, SiCN, SiOC, SiON, or SiOCN.

A second bonding dielectric layer 122 may be further formed on the structure. The structure may be flipped over and pressed to be bonded to the substrate for bonding structure BS such that the second bonding dielectric layer 122 and the first bonding dielectric layer 104 may be dielectric-dielectric bonded to each other. Accordingly, the base substrate 101 may be positioned on an upper portion of the bonded structure, and the third mold structure PS3 may form the first bonding stack structure positioned adjacent to the substrate for bonding structure BS.

In the example embodiments in FIG. 5A, this process may be performed after the first mold structure PS1 is formed, and the second and third mold structures PS2 and PS3 may be formed thereafter. For example, the process described below with reference to FIGS. 10D and 10E may be performed, the first channel sacrificial layers 116a and the first contact sacrificial layers 119a may be formed again, the second and third mold structures PS2 and PS3 may be formed, and the process described below with reference to FIG. 10F may be performed. Similarly, in the example embodiments in FIG. 5B, this process may be performed after the first and second mold structures PS1 and PS2 are formed, and the third mold structure PS3 may be formed thereafter.

Referring to FIG. 10D, the base substrate 101 may be removed from the upper portion of the first bonding stack structure.

The base substrate 101 positioned on the upper portion of the first bonding stack structure may be selectively removed with respect to the lowermost interlayer insulating layer 120L, the first channel sacrificial layers 116a, and the first contact sacrificial layers 119a. For example, a portion of the base substrate 101 may be removed from the upper surface by a grinding process, a portion may be removed by a planarization process such as a chemical mechanical polishing (CMP) process, and the other portion may be removed by an etching process such as wet etching. Accordingly, lower ends of the first channel sacrificial layers 116a and the first contact sacrificial layers 119a may be exposed and may protrude to a lowermost interlayer insulating layer 120L.

Referring to FIG. 10E, the first to third channel sacrificial layers 116a, 116b, and 116c and the first to third contact sacrificial layers 119a, 119b, and 119c may be removed, thereby forming first and second vertical holes OP1 and OP2.

The first to third channel sacrificial layers 116a, 116b, and 116c and the first to third contact sacrificial layers 119a, 119b, and 119c may be selectively removed with respect to the mold structure PS. For example, when the first to third channel sacrificial layers 116a, 116b, and 116c and the first to third contact sacrificial layers 119a, 119b, and 119c include a carbon-based material, the layers may be removed by a strip process. The first vertical holes OP1 may be regions from which the first to third channel sacrificial layers 116a, 116b, and 116c are removed, and the second vertical holes OP2 may be regions from which the first to third contact sacrificial layers 119a, 119b, and 119c are removed. Each of the second vertical holes OP2 may have a diameter greater than that of each of the first vertical holes OP1. Each of the first and second vertical holes OP1 and OP2 may have a shape in which three portions having a shape having a width increasing toward the substrate for bonding structure BS are vertically stacked.

Referring to FIG. 10F, channel structures CH may be formed, gate electrodes 130 may be formed, gate contact plugs 170 and through-contact plug THV may be formed.

The channel structures CH may be formed by depositing at least a portion of a channel dielectric layer 145, a channel layer 140, a channel filling insulating layer 147 and a channel pad 149 in order in the first vertical holes OP1. The channel dielectric layer 145 may be formed to have a uniform thickness using an atomic layer deposition (ALD) or chemical vapor deposition (CVD) process. In this process, the entirety or a portion of the channel dielectric layer 145 may be formed, and a portion extending vertically along the channel structures CH may be formed in this process. The channel layer 140 may be formed on the channel dielectric layer 145 in the channel holes. A channel filling insulating layer 147 may be formed to fill the channel holes and may be an insulating material. The channel pad 149 may be formed of a conductive material, for example, polycrystalline silicon. Accordingly, channel structures CH each including first to third channel portions CH1, CH2, and CH3 may be formed.

Preliminary contact insulating layers forming the contact insulating layers 160 may be formed in the second vertical holes OP2, vertical sacrificial layers filling the second vertical holes OP2 may be formed, and the sacrificial insulating layers 118 may be removed.

First, contact tunnel portions may be formed by partially removing the sacrificial insulating layers 118 exposed through the second vertical holes OP2, and the preliminary contact insulating layers may be formed. The preliminary contact insulating layers may be formed on a sidewall of the second vertical holes OP2, and may fill the contact tunnel portions. The contact tunnel portions may be formed to a relatively short length in the sacrificial insulating layers 118 of which ends are positioned in the gate pad regions GP, and may be formed to have a relatively long length in the sacrificial insulating layers 118 in a lower portion thereof. The vertical sacrificial layers may fill the second vertical holes OP2 and may fill the contact tunnel portions of the gate pad regions GP. The vertical sacrificial layers may include a material different from that of the preliminary contact insulating layers, for example, polycrystalline silicon.

Thereafter, openings penetrating the sacrificial insulating layers 118 and the interlayer insulating layers 120 in a position of the first isolation regions MS (see FIGS. 1 and 2B) and extending to the substrate for bonding structure BS may be formed. An etchant may be provided through the openings and the sacrificial insulating layers 118 may be removed. The sacrificial insulating layers 118 may be selectively removed with respect to the channel structures CH, the interlayer insulating layers 120, and the preliminary contact insulating layers, for example, using a wet etching process.

The gate electrodes 130 may be formed by depositing a conductive material on the regions from which the sacrificial insulating layers 118 are removed. The conductive material may include a metal, polycrystalline silicon, or a metal silicide material. In some example embodiments, a portion of the channel dielectric layer 145 may be formed preferentially before the gate electrodes 130 are formed. Accordingly, a gate structure GS including first to third stack structures GS1, GS2, and GS3 may be formed. After the gate electrodes 130 are formed, an insulating material may be filled in the openings formed to correspond to the first isolation regions MS.

Gate contact plugs 170 and through-contact plug THV may be formed by removing the vertical sacrificial layers from the second vertical holes OP2, partially removing the exposed preliminary contact insulating layers, and depositing the conductive material.

The preliminary contact insulating layers may be completely removed from the contact tunnel portions positioned in the gate pad regions GP and may remain therebelow and may form the contact insulating layers 160. The gate contact plugs 170 may be formed to have horizontal extension portions extending horizontally in the end regions of the gate electrodes 130 positioned in the gate pad regions GP and may thus be physically and electrically connected to the gate electrodes 130.

In the example embodiments in FIG. 7, in this process, after the gate electrodes 130 are formed, the lowermost gate electrode 130L’, the string channel structures SCH, and the lower contacts 175 may be further formed. In the example embodiments in FIG. 8A, in this process, after the gate electrodes 130 are formed, the gate contact plugs 170g may be formed.

Referring to FIG. 10G, the second interconnection structure and the second bonding structure may be formed, and the second semiconductor structure S2 and the first semiconductor structure S1 may be bonded to each other.

A fifth cell region insulating layer 197 may be formed on the channel structures CH and the gate contact plugs 170 in FIG. 10F, and studs 180, first cell contact plugs 185, and first cell interconnection lines 187 forming the second interconnection structure may be formed in order. Second bonding vias 195, second bonding pads 198, and second bonding insulating layer 199 forming the second bonding structure may be further formed on the second interconnection structure.

A first semiconductor structure S1 may be prepared by forming circuit elements 220, a first interconnection structure, and a first bonding structure forming a peripheral circuit region on the substrate 201.

Device isolation layers 210 may be formed in the substrate 201, and a circuit channel dielectric layer 222 and a circuit gate electrode 225 may be formed in order on the substrate 201. The device isolation layers 210 may be formed, for example, by a shallow trench isolation (STI) process. The circuit channel dielectric layer 222 and the circuit gate electrode 225 may be formed using ALD or CVD. The circuit channel dielectric layer 222 may be formed of silicon oxide, and the circuit gate electrode 225 may be formed of at least one of polycrystalline silicon or a metal silicide layer, but some example embodiments thereof is not limited thereto. Thereafter, a spacer layer 224 and source/drain regions 205 may be formed on both sidewalls of the circuit channel dielectric layer 222 and the circuit gate electrode 225. In example embodiments, the spacer layer 224 may include a plurality of layers. The source/drain regions 205 may be formed by performing an ion implantation process.

The circuit contact plugs 270 of the first interconnection structure and the second bonding vias 295 of the first bonding structure may be formed by partially forming a peripheral region insulating layer 290, etching and removing a portion, and filling a conductive material. The circuit interconnection lines 280 of the first interconnection structure and the first bonding pads 298 of the first bonding structure may be formed, for example, by depositing a conductive material and patterning the material. The second bonding pads 298 may be formed such that an upper surface is exposed through the second bonding insulating layer 299.

The peripheral region insulating layer 290 may include a plurality of insulating layers. A portion of the peripheral region insulating layer 290 may be formed in each of the processes of forming the first interconnection structure and the first bonding structure. By this process, the first semiconductor structure S1 may be prepared.

The first semiconductor structure S1 and the second semiconductor structure S2 may be connected to each other by bonding the first bonding pads 298 to the second bonding pads 198 by annealing and/or applying pressure. Also, the first bonding insulating layer 299 and the second bonding insulating layer 199 may also be bonded to each other. The second semiconductor structure S2 may be disposed upside down on the first semiconductor structure S1 such that the second bonding pads 198 may be disposed downwardly, and bonding may be performed. Accordingly, the second bonding stack structure may be formed.

Referring to FIG. 10H, the substrate for bonding structure BS may be removed from an upper portion of the second bonding stack structure, and the common source layer 105 may be formed.

The substrate for bonding 103 of the substrate for bonding structure BS may be removed in the same manner as the base substrate 101 described above. Thereafter, upper ends of the channel structures CH may be exposed. To this end, the first and second bonding dielectric layers 103, 122 may be removed, and a portion of the third cell region insulating layer 194 may also be removed. The channel dielectric layer 145 may be removed from the upper ends of the exposed channel structures CH and the channel layers 140 may be exposed. The common source layer 105 may be formed in the first region R1 to cover the exposed channel layers 140. In this process, the upper ends of the gate contact plugs 170 may also be exposed to the gate structure GS, but example embodiments thereof are not limited thereto. In some example embodiments, at least a portion of the third cell region insulating layer 194 and the first and second bonding dielectric layers 103, 122 may remain on and around the gate contact plugs 170.

Thereafter, referring to FIG. 2A together, a fourth cell region insulating layer 196 may be formed on gate contact plugs 170 and common source layer 105, and second cell contact plugs 188 and second cell interconnection lines 189 connected to the gate contact plugs 170 and the common source layer 105 may be formed, thereby manufacturing a semiconductor device 100.

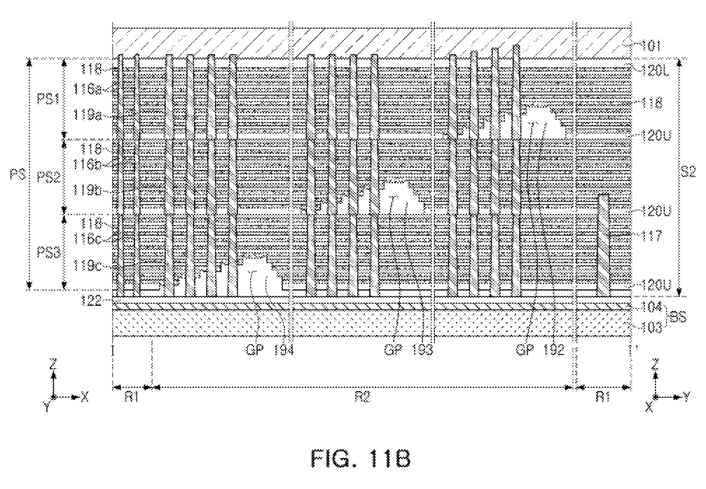

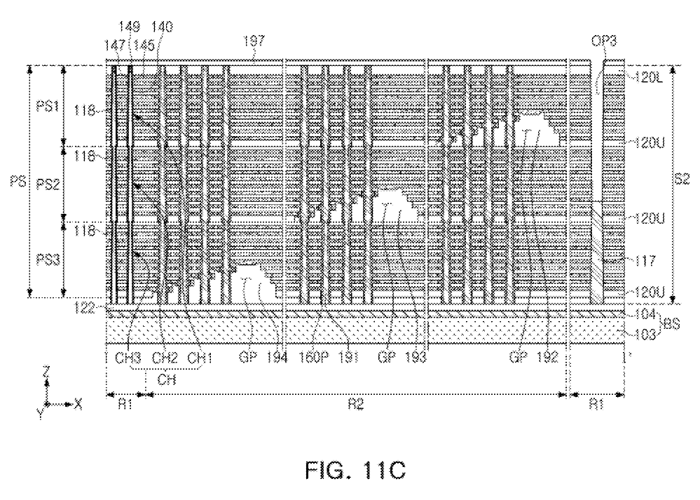

FIGS. 11A, 11B and 11C are cross-sectional views illustrating a method of manufacturing a semiconductor device according to example embodiments, each illustrating a cross-sectional surface corresponding to FIG. 9A.

Referring to FIG. 11A, first, as described above with reference to FIGS. 10A and 10B, a first mold structure PS1, first channel sacrificial layers 116a, first contact sacrificial layers 119a, second mold structure PS2, second channel sacrificial layers 116b, and second contact sacrificial layers 119b may be formed, and a third mold structure PS3 may be formed.

Thereafter, openings SH1, SH2, and SH3 penetrating the third mold structure PS3 may be formed. Among the openings SH1, SH2, and SH3, the holes SH1 corresponding to the third channel portions CH3 in FIGS. 9A and 9B may be formed to have the smallest first diameter, the holes SH2 corresponding to the third contact portions MC3 may be formed to have a second diameter greater than the first diameter, and the trench SH3 corresponding to the first portion MS_1 of the first isolation region MSi may have a third width greater than the first and second diameters and may extend in the X-direction. The holes SH1 and SH2 may be formed to expose the second channel sacrificial layers 116b and the second contact sacrificial layers 119b. The trench SH3 may have a shape and a width different from those of the holes SH1 and SH2 and may not have a vertical sacrificial layer in a lower portion, such that the trench SH3 may be formed relatively deeply.

Referring to FIG. 11B, first, as described above with reference to FIG. 10B, third channel sacrificial layers 116c and third contact sacrificial layers 119c filling the holes SH1 and SH2, and third isolation sacrificial layer 117 filling the trench SH3 may be formed.

Thereafter, as described above with reference to FIG. 10C, the structure may be flipped over and bonded to a substrate for bonding structure BS.

Referring to FIG. 11C, first, as described above with reference to FIG. 10D, the base substrate 101 may be removed, and as described above with reference to FIG. 10E, the first to third channel sacrificial layers 116a, 116b, and 116c and the first to third contact sacrificial layers 119a, 119b, and 119c may be removed, thereby forming the first and second vertical holes OP1 and OP2. As described above with reference to FIG. 10F, channel structures CH may be formed in the first vertical holes OP1, and preliminary contact insulating layers 160P and vertical sacrificial layers 191 forming contact insulating layers 160 may be formed in the second vertical holes OP2.

Thereafter, a fifth cell region insulating layer 197 may be partially formed, a third vertical hole OP3 penetrating a portion of the first isolation structure PS1 and the second isolation structure PS2 and expose the third isolation sacrificial layer 117 may be formed. The third vertical hole OP3 may have a shape in which a width of an upper portion is greater than a width of a lower portion depending on an aspect ratio. When the third vertical hole OP3 is formed, the third isolation sacrificial layer 117 may function as an etch-stop layer. In some example embodiments, the process of forming the third vertical hole OP3 may be performed before the other process, for example, removing the first to third channel sacrificial layers 116a, 116b, and 116c and the first to third contact sacrificial layers 119a, 119b, and 119c.

Thereafter, by removing the third isolation sacrificial layer 117 exposed through the third vertical hole OP3, the third vertical hole OP3 may extend. Thereafter, as described above with reference to FIG. 10F, the sacrificial insulating layers 118 may be removed through the extended third vertical hole, gate electrodes 130 may be formed, and the vertical sacrificial layers 191 may be removed from the second vertical holes OP2, a portion of the exposed preliminary contact insulating layers 160P may be removed, and a conductive material may be deposited, thereby forming gate contact plugs 170.

Thereafter, by performing the same processes described above with reference to FIGS. 10G, 10H, and 2A, the semiconductor device 100i in FIGS. 9A and 9B may be manufactured.

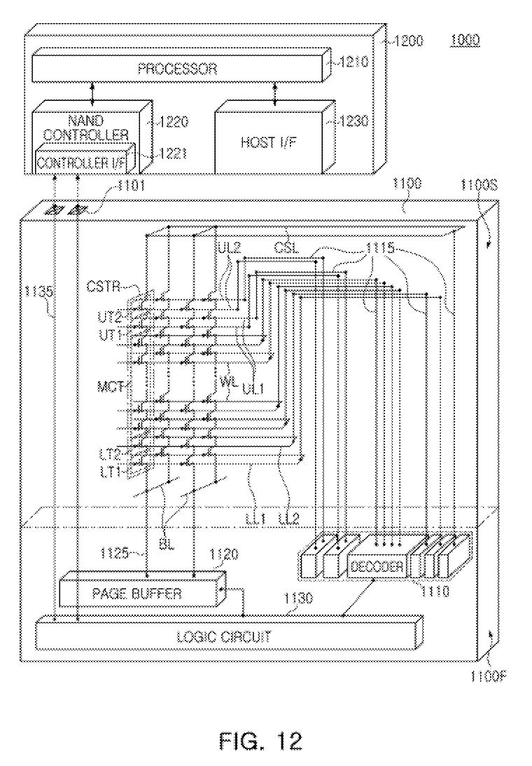

FIG. 12 is a view illustrating a data storage system including a semiconductor device according to example embodiments.

Referring to FIG. 12, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiments with reference to FIGS. 1, 2A, 2B, 3, 4A, 4B, 4C, 5A, 5B, 6A, 6B, 7, 8A, 8B, 9A and 9B. The semiconductor device 1100 may include a first structure 1100F and a second structure 1100S on the first structure 1100F. In the example embodiments, the first structure 1100F may be disposed on the side of the second structure 1100S. The first structure 1100F may be configured as a peripheral circuit structure including a decoder circuit 1110, a page buffer 1120, and a logic circuit 1130. The second structure 1100S may be configured as a memory cell structure including a bitline BL, a common source line CSL, wordlines WL, first and second gate upper lines UL1 and UL2, first and second gate lower lines LL1 and LL2, and memory cell strings CSTR between the bitline BL and the common source line CSL.

In the second structure 1100S, each of the memory cell strings CSTR may include a plurality of memory cell transistors MCT disposed between lower transistors LT1 and LT2 adjacent to a common source line CSL, upper transistors UT1 and UT2 adjacent to a bitline BL, and lower transistors LT1 and LT2 and upper transistors UT1 and UT2. The number of lower transistors LT1 and LT2 and the number of upper transistors UT1 and UT2 may be varied in example embodiments.

In example embodiments, the upper transistors UT1 and UT2 may include string select transistors, and the lower transistors LT1 and LT2 may include ground select transistors. The gate lower lines LL1 and LL2 may be configured as gate electrodes of the lower transistors LT1 and LT2, respectively. The wordlines WL may be configured as gate electrodes 130 of the memory cell transistors MCT, and the gate upper lines UL1 and UL2 may be configured as gate electrodes of the upper transistors UT1 and UT2, respectively.

In example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used for an erase operation of erasing data stored in the memory cell transistors MCT using the GIDL phenomenon.

Common source line CSL, first and second gate lower lines LL1 and LL2, wordlines WL, and first and second gate upper lines UL1 and UL2 may be electrically connected to the decoder circuit 1110 through first interconnections 1115 extending from the first structure 1100f to the second structure 1100S. The bitlines BL may be electrically connected to the page buffer 1120 through the second interconnections 1125 extending from the first structure 1100f to the second structure 1100S.

In the first structure 1100F, the decoder circuit 1110 and the page buffer 1120 may perform a control operation for at least one select memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection 1135 extending from the first structure 1100f to the second structure 1100S.

The controller 1200 may include a processor 1210, a NAND controller 1220, and a host interface 1230. In example embodiments, the data storage system 1000 may include a plurality of semiconductor devices 1100, and in this case, the controller 1200 may control a plurality of semiconductor devices 1100.

The processor 1210 may control operations of the data storage system 1000 including the controller 1200. The processor 1210 may operate according to predetermined firmware and may access the semiconductor devices 1100 by controlling the NAND controller 1220. The NAND controller 1220 may include a controller interface 1221 handling communication with the semiconductor device 1100. Through the controller interface 1221, control commands for controlling the semiconductor device 1100, data to be written in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

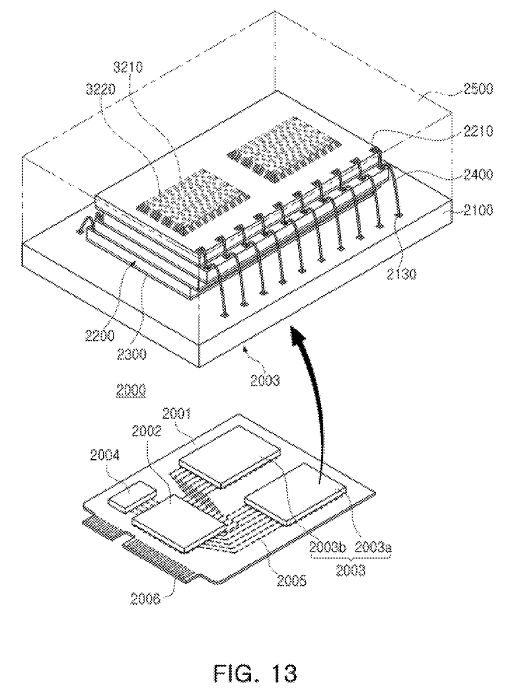

FIG. 13 is a perspective view illustrating a data storage system including a semiconductor device in example embodiments.

Referring to FIG. 13 a data storage system 2000 in some example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a bonding structure 2400 electrically connecting the semiconductor chips 2200 to the package substrate 2100, and a molding layer 2500 covering the semiconductor chips 2200 and the bonding structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 12. Each of the semiconductor chips 2200 may include gate stack structures 3210 and channel structures 3220. Each of the semiconductor chips 2200 may include the semiconductor device described in the aforementioned example embodiments with reference to FIGS. 1, 2A, 2B, 3, 4A, 4B, 4C, 5A, 5B, 6A, 6B, 7, 8A, 8B, 9A and 9B.

In the example embodiments, the bonding structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the bonding structure 2400 of a bonding wire method.

In the example embodiments, the controller 2002 and the semiconductor chips 2200 may be included in a single package. In some example embodiments, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned example embodiments, by aligning the ends of the channel structures and the gate contact plugs in the insulating layer, a semiconductor device and a data storage system including the same having improved reliability and electrical properties may be provided.

In example embodiments of the present disclosure, a method of manufacturing a semiconductor device includes forming a first mold structure by alternately stacking interlayer insulating layers and sacrificial insulating layers on a base substrate, forming first vertical sacrificial layers extending into the first mold structure and the base substrate; forming a first bonding stack structure by reverting and bonding a structure including the base substrate such that the first mold structure is disposed downwardly on a substrate structure for bonding; removing the base substrate in an upper portion of the first bonding stack structure; forming first and second vertical holes by removing the first vertical sacrificial layers exposed by removing the base substrate; forming channel structures in the first vertical holes; forming gate electrodes by removing the sacrificial insulating layers and depositing a conductive material; forming gate contact plugs in the second vertical holes; forming a second interconnection structure including bitlines and second bonding pads on the channel structures and the gate contact plugs; preparing a first semiconductor structure including a substrate, circuit elements on the substrate, a first interconnection structure electrically connected to the circuit elements, and first bonding pads on the first interconnection structure; forming a second bonding stack structure by bonding the first semiconductor structure to a second semiconductor structure including the gate electrodes such that the first bonding pads and the second bonding pads are connected to each other; removing the substrate structure for bonding from the second bonding stack structure and exposing ends of the channel structures; and forming a common source layer on the ends of the channel structures.

At least a portion of the first vertical sacrificial layers may extend to different depths in the base substrate.

The substrate structure for bonding may include a substrate for bonding and a first bonding dielectric layer on the substrate for bonding.

Forming the first bonding stack structure may include forming a second bonding dielectric layer on the first mold structure and the first vertical sacrificial layers; and pressurizing the substrate structure for bonding and the structure including the base substrate such that the first bonding dielectric layer and the second bonding dielectric layer are bonded to each other.

The second vertical holes may have a diameter greater than a diameter of the first vertical holes.

In the first bonding stack structure, each of the first vertical sacrificial layers may have an inclined side surface such that a width increases toward the substrate structure for bonding.

The channel structures may include first channel portions formed in regions from which the first vertical sacrificial layers are removed, and in the second bonding stack structure, each of the first channel portions may have an inclined side surface such that a width decreases toward the first semiconductor structure.

The method may further include supplying an etchant into the first and second vertical holes and expanding upper ends of the first and second vertical holes.

The method may further include forming a second mold structure and a second vertical sacrificial layer extending into the second mold structure and connected to each of the first vertical sacrificial layers, respectively, on the first mold structure, before the forming of the first bonding stack structure.

The method may further include forming a second mold structure and a second vertical sacrificial layer extending into the second mold structure and connected to the first vertical sacrificial layers, respectively, on the first mold structure, after the forming of the first bonding stack structure.

While this specification contains many specific embodiment details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

While the example embodiments have been illustrated and described above, it will be configured as apparent to those skilled in the art that modifications, variations, and combinations of the example embodiments could be made without departing from the scope of the present disclosure as defined by the appended claims.

What is claimed is:

1. A semiconductor device, comprising:
a first semiconductor structure including a substrate, circuit elements on the substrate, a first interconnection structure on the circuit elements, and first bonding pads on the first interconnection structure; and
a second semiconductor structure on the first semiconductor structure,
wherein the second semiconductor structure includes
gate electrodes spaced apart from each other in a first direction perpendicular to an upper surface of the substrate;
interlayer insulating layers alternately stacked with the gate electrodes;
channel structures extending into the gate electrodes in the first direction, wherein each of the channel structures includes a channel layer;
gate contact plugs extending into the gate electrodes in the first direction and electrically connected to respective ones of the gate electrodes;
common source layers covering upper ends of the channel structures and in contact with the channel layers;
second interconnection structures including bitlines electrically connected to respective ones of the channel structures below lower ends of the channel structures; and
second bonding pads below the second interconnection structures and connected to the first bonding pads,
wherein each of the channel structures includes a plurality of channel portions stacked in the first direction,
wherein each of the gate contact plugs includes a plurality of contact portions stacked in the first direction,
wherein, in at least one of the plurality of channel portions, a width of an upper surface is a same as or greater than a width of a lower surface, and
wherein, in at least one of the plurality of contact portions, a width of an upper surface is a same as or greater than a width of a lower surface.

2. The semiconductor device of claim 1, wherein the lower ends of the channel structures and lower ends of the gate contact plugs are positioned at a same level.

3. The semiconductor device of claim 1, wherein lower surfaces of the channel structures and lower surfaces of the gate contact plugs are coplanar with a lower surface of a lowermost interlayer insulating layer among the interlayer insulating layers.

4. The semiconductor device of claim 1, wherein the second interconnection structures include studs connected to the lower ends of the channel structures and lower ends of the gate contact plugs.

5. The semiconductor device of claim 4, wherein a width of each of lower surfaces of the gate contact plugs is greater than a width of each of upper surfaces of the studs.

6. The semiconductor device of claim 1, wherein each of the channel structures includes a channel pad forming the lower end and connected to the channel layer.

7. The semiconductor device of claim 1,
wherein the plurality of channel portions include a first channel portion and a second channel portion stacked in order from a lower portion, and the plurality of contact portions include a first contact portion and a second contact portion stacked in order from a lower portion,
wherein the first channel portion includes an upper region and a lower region below the upper region, wherein a width of the upper region decreases toward the substrate and a width of the lower region increases toward the substrate, and
wherein the first contact portion includes an upper region and a lower region below the upper region, wherein a width of the upper region decreases toward the substrate and a width of the lower region increases toward the substrate below the upper region.

8. The semiconductor device of claim 7, wherein, in the first channel portion, the upper region has a first height in the first direction, and the lower region has a second height smaller than the first height in the first direction.

9. The semiconductor device of claim 7,
wherein the second channel portion includes an upper region and a lower region below the upper region, wherein a width of the upper region decreases toward the substrate and a width of the lower region increases toward the substrate, and
wherein the second contact portion includes an upper region and a lower region below the upper region, wherein a width of the upper region decreases toward the substrate and a width of the lower region increases toward the substrate.

10. The semiconductor device of claim 1, wherein, in each of the plurality of channel portions, a width of an upper surface is greater than a width of a lower surface.

11. The semiconductor device of claim 1, wherein a width of upper ends of the gate contact plugs are greater than a width of upper ends of the channel structures.

12. The semiconductor device of claim 1, wherein the channel structures have a width that changes discontinuously between the plurality of channel portions.

13. The semiconductor device of claim 1,
wherein the second semiconductor structure includes an isolation region extending into the gate electrodes and extending in a second direction perpendicular to the first direction, and
wherein the isolation region includes a first portion and a second portion below the first portion, wherein a width of the first portion decreases toward the substrate and a width of the second portion increases toward the substrate.

14. A semiconductor device, comprising:
gate electrodes spaced apart from each other in a first direction perpendicular to an upper surface of a substrate;
interlayer insulating layers alternately stacked with the gate electrodes;
channel structures extending into the gate electrodes in the first direction, wherein each of the channel structures includes a channel layer;
gate contact plugs extending into the gate electrodes in the first direction, wherein the each of the gate contact plugs are electrically connected to respective ones of the gate electrodes;
common source layers in contact with the channel layers on the channel structures;
a cell region insulating layer below the channel structures and the gate contact plugs; and
bitlines electrically connected to respective ones of the channel structures in the cell region insulating layer,
wherein each of the channel structures includes first to third channel portions stacked in order from a lower portion,
wherein at least the third channel portion includes a region having an inclined side surface, and a width of the region decreases toward the substrate, and
wherein lower ends of the channel structures and lower ends of the gate contact plugs are in an insulating structure including a lowermost interlayer insulating layer among the interlayer insulating layers and the cell region insulating layer.

15. The semiconductor device of claim 14, wherein the lower ends of the gate contact plugs are at a same level as the lower ends of the channel structures.

16. The semiconductor device of claim 14, wherein each of the first and second channel portions includes a region having an inclined side surface and a width of each of these regions decreases toward the substrate.

17. The semiconductor device of claim 14, wherein at least one of the first and second channel portions includes a region having an inclined side surface and a width of each of these regions increases toward the substrate.

18. The semiconductor device of claim 14,
wherein each of the gate contact plugs includes first to third contact portions stacked in order from a lower portion, and
wherein at least the third contact portion includes a region having an inclined side surface and a width of the region decreases toward the substrate.

19. A data storage system, comprising:
a semiconductor storage device including a first semiconductor structure including circuit elements, a second semiconductor structure on the first semiconductor structure, and an input/output pad electrically connected to the circuit elements; and
a controller electrically connected to the semiconductor storage device through the input/output pads,
wherein the second semiconductor structure includes
gate electrodes spaced apart from each other in a first direction perpendicular to an upper surface of the first semiconductor structure;
interlayer insulating layers alternately stacked with the gate electrodes;
channel structures extending into the gate electrodes in the first direction, wherein each of the channel structures includes a channel layer;
gate contact plugs extending into the gate electrodes in the first direction and electrically connected to respective ones of the gate electrodes;
a common source layer in contact with the channel layer on the channel structures;
a cell region insulating layer below the channel structures and the gate contact plugs; and
bitlines electrically connected to respective ones of the channel structures in the cell region insulating layer,
wherein each of the channel structures includes first, second, and third channel portions stacked in order from a lower portion,
wherein each of the gate contact plugs includes first, second, and third contact portions stacked in order from a lower portion, and
wherein each of the third channel portion and the third contact portion includes a region having an inclined side surface and a width of each of the regions decreases toward the upper surface of the first semiconductor structure.

20. The data storage system of claim 19, wherein lower ends of the channel structures and lower ends of the gate contact plugs are in an insulating structure including a lowermost interlayer insulating layer among the interlayer insulating layers and the cell region insulating layer.
